(19) United States
(12) Patent Application Publication
(10) Pub. No.: US 2025/0071911 A1
(43) Pub. Date: Feb. 27, 2025

(54) ANISOTROPIC CONDUCTIVE SUBSTRATES AND METHODS OF USE

(71) Applicant: BAE Systems Information and Electronic Systems Integration Inc., Nashua, NH (US)

(72) Inventors: Nathaniel P. Wyckoff, Marion, IA (US); Jacob R. Mauermann, Marion, IA (US); Benjamin Terry, Cedar Rapids, IA (US); Justin D. Smith, North Liberty, IA (US)

(73) Assignee: BAE Systems Information and Electronic Systems Integration Inc., Nashua, NH (US)

(21) Appl. No.: 18/452,984

(22) Filed: Aug. 21, 2023

(51) Int. Cl. H05K 3/36

(52) U.S. Cl. CPC H05K 3/368

(57) ABSTRACT

A method fabricating at least one universal substrate from a batch product. The method includes steps of: providing a preform having a predetermined profile; wrapping a plurality of conductors about an outer surface of the preform; injecting a nonconductive matrix between conductors of the plurality of conductors, wherein the nonconductive matrix permeates between interstitial spaces of the plurality of conductors to isolate some conductors of the plurality of conductors from one another; forming the batch product that includes the plurality of conductors and the nonconductive matrix; and wafering at least one section of the batch product to form the at least one universal substrate. The plurality of conductors of the at least one universal substrate defines a first connection surface, a second connection surface opposite to the first connection surface, and a plurality of conductive pathways defined between the first connection surface and the second connection surface.

### TECHNICAL FIELD

The present disclosure relates to universal interconnects or substrates and methods of use.

### BACKGROUND ART

In the electronics market, electronic devices and integrated circuits include numerous products and/or components based on the implementation of these electronic devices and integrated circuits in a desired electrical system or product. Generally, the devices and components of these electronic devices and integrated circuits are positioned in a vertical arrangement to conserve space and the overall footprint of the device or circuit. With such arrangement, these electronic devices and integrated circuits must precisely connect each device and component in vertical planes at complex positions while avoiding electrical issues.

To combat these difficulties, electronic devices and integrated circuits in the current market may use vertical electrical connection products, such as through substrate vias or through-chip vias, for creating electrical connections. While these products are desired in electronic devices and integrated circuits, these products still provide issues when constructing electronic devices and integrated circuits. In one instance, through substrate vias and other vertical electrical connection products of the like must be formed from a nonconductive base material, such as passivated silicon, glass, and other similar nonconductive base materials. While these nonconductive base materials are suitable, these materials are rather expensive and difficult to source when forming these products. In another instance, through substrate vias and other vertical electrical connection products are designed to a specific circuit or device. With such specificity, the act of manufacturing these through substrate vias and similar products requires fabricating vias and/or channels through the base material in order to lay out conductive tracing and/or material for the various circuits. Such fabrication requires machinery to precisely cut these vias and channels which results in increase costs, increase build times, and loss of leveraging these products into other electronic devices and integrated circuits.

Furthermore, these products are designed to be used with solder balls or plated metal pillars when provided in electronic devices and integrated circuits. When solder balls are used in these electronic devices and integrated circuits, solder balls require individual placement on through substrate vias and the devices, which necessitates precise alignment of a mask or ball drop machine with a part. When plated metal pillars are used in these electronic devices and integrated circuits, the technique of plating requires wet chemicals to be used; however, such techniques of plating can be difficult in acquiring a uniform thickness plating when these products have varying heights and thicknesses.

### SUMMARY OF THE INVENTION

The presently disclosed universal substrate enables designers of electronic devices (such as device-on-device products) or integrated circuits to connect varying types of device and circuits with the universal substrate given a multipurpose pattern and/or configuration. The universal substrate is conductive, either electrically or thermally, in a first or vertical axis, while being nonconductive, either electrically or thermally, in a second axis that is orthogonal to the first axis. The universal substrate also includes a plurality of conductors that is provided in a multipurpose pattern and/or configuration for allowing randomized and/or unplanned electrical connections between devices and components. As such, the universal substrate disclosed herein addresses some of the inadequacies of previously known through substrate via products.

In one aspect, an exemplary embodiment of the present disclosure may provide a universal substrate. The universal substrate may include a plurality of conductors that defines a first connection surface, a second connection surface opposite to the first connection surface, and a plurality of conductive pathways defined between the first connection surface and the second connection surface. The universal substrate may also include a nonconductive matrix that surrounds the plurality of conductors and is configured to isolate each conductor of the plurality of conductors from one another along an axis that is perpendicular to the plurality of conductive pathways. The universal substrate enables conductivity between at least two devices at any two positions along the first connection surface and the second connection surface that are coaxial with one another.

This exemplary embodiment or another exemplary embodiment may further include that the plurality of conductors is one of electrically conductive between the first connection surface and the second connection surface to provide electrical communication between the at least two devices and thermally conductive between the first connection surface and the second connection surface to provide directional heat flow through the nonconductive matrix. This exemplary embodiment or another exemplary embodiment may further include that each conductor of the plurality of conductors comprises: a first connection end defining a portion of the first connection surface; a second connection end opposite to the first connection end and defining a portion of the second connection surface; and a conductive pathway defined between the first connection end and the second connection end for enabling one of electrical conductivity and thermal conductivity. This exemplary embodiment or another exemplary embodiment may further include a diameter defined by each conductor of the plurality of conductors between the first connection end and the second connection end; wherein the diameter of each conductor of the plurality of conductors is equal to one another. This exemplary embodiment or another exemplary embodiment may further include at least one set of conductors of the plurality of conductors, wherein each conductor of the at least one set of conductors defines a first diameter; and at least another set of conductors of the plurality of conductors, wherein each conductor of the at least another set of conductors defines a second diameter that is greater than the first diameter defined by each conductor of the at least one set of conductors. This exemplary embodiment or another exemplary embodiment may further include a pair of first bonding pads collectively defined by first connection ends of at least one set of conductors of the plurality of conductors and second connection ends of the at least one set of conductors of the plurality of conductors; and a pair of second bonding pads defined by first connection ends of at least another set of conductors of the plurality of conductors and second connection ends of the at least another set of conductors of the plurality of conductors; wherein the pair of first bonding pads and the pair of second bonding pads have diameters equal to one another or different to one another. This exemplary embodiment or another exemplary embodiment may further include that the nonconductive matrix comprises: a first end and a second end longitudinally opposite to the first end; a first side extending between the first end and the second end; and a second side extending between the first end and the second end and transversely opposite to the first side; wherein the nonconductive matrix is a solid, unitary member between the first end and the second end and between the first side and the second side to encapsulates the plurality of conductors. This exemplary embodiment or another exemplary embodiment may further include that the nonconductive matrix comprises: a set of first nonconductive pathways defined between the first end and the second end and being perpendicular to each conductive pathway of the plurality of conductive pathways; wherein the set of first nonconductive pathways isolates electrical conductivity and thermal conductivity between each conductor of the plurality of conductors from one another. This exemplary embodiment or another exemplary embodiment may further include that the nonconductive matrix comprises: a set of second nonconductive pathways defined between the first side and the second side and being perpendicular to each conductive pathway of the plurality of conductive pathways; wherein the set of second nonconductive pathways isolates electrical conductivity and thermal conductivity between each conductor of the plurality of conductors from one another. This exemplary embodiment or another exemplary embodiment may further include that the plurality of conductivity comprises: a set of first conductors conductively engaged with a first electronic device of the at least two devices at the first connection surface and a second electronic device of the at least two devices at the second connection surface; and a set of second conductors conductivity disengaged with the at least two devices at the first connection surface and the second connection surface; wherein at least one conductor of the set of second conductors separates a first group of the set of first conductors and a second group of the set of first conductors from one another. This exemplary embodiment or another exemplary embodiment may further include that the plurality of conductivity comprises: a set of first conductors conductively engaged with a first electronic device of the at least two devices at the first connection surface and a second electronic device of the at least two devices at the second connection surface; a set of second conductors conductivity disengaged with the at least two devices at the first connection surface and the second connection surface; and a set of third conductors conductively engaged with the first electronic device at the first connection surface and the second electronic device at the second connection surface; wherein at least two conductors of the set of third conductors shield at least one conductor of the set of first conductors. This exemplary embodiment or another exemplary embodiment may further include at least one conductive tracing operably engaged with at least one of the first connection surface and the second connection surface; wherein the conductive tracing is adapted to provide conductivity between a first electronic device of the at least two devices and a second electronic device of the at least two devices that are non-coaxial with one another. This exemplary embodiment or another exemplary embodiment may further include that the plurality of conductors is arranged in a uniform pattern inside the nonconductive matrix or arranged in a non-uniform pattern inside of the nonconductive matrix.

In another aspect, an exemplary embodiment of the present disclosure may provide a method. The method includes steps of providing a plurality of conductors in one of a uniform pattern or in a non-uniform pattern; forming a nonconductive matrix around each conductor of the plurality of conductors to create a universal substrate; effecting at least one device to be connected with a first connection surface of the universal substrate defined by the plurality of conductors; effecting at least another device to be connected with a second connection surface of the universal substrate defined by the plurality of conductors; and enabling conductivity between the at least one device and the at least another device by a plurality of conductive pathways defined between the first connection surface and the second connection surface.

This exemplary embodiment or another exemplary embodiment may further include that the step of forming the nonconductive matrix around each conductor of the plurality of conductors further comprising: insulating each conductor of the plurality of conductors from one another, by the nonconductive matrix, along axes that are perpendicular to the plurality of conductive pathways. This exemplary embodiment or another exemplary embodiment may further include that the steps of effecting the at least one device to be connected with the first connection surface and effecting the at least another device to be connected with the second connection surface further includes: connecting the at least one device and the at least another device with at least one conductor of the plurality of conductors such that the at least one device and the at least another device are coaxial with one another with respect to the at least one conductor or offset with one another with respect to the at least one conductor. This exemplary embodiment or another exemplary embodiment may further include that the steps of effecting the at least one device to be connected with the first connection surface and effecting the at least another device to be connected with the second connection surface further includes: connecting the at least one device with a pair of first bonding pads collectively defined by first connection ends of at least one set of conductors of the plurality of conductors and second connection ends of the at least one set of conductors of the plurality of conductors; and connecting the at least another device with a pair of second bonding pads defined by first connection ends of at least another set of conductors of the plurality of conductors and second connection ends of the at least another set of conductors of the plurality of conductors; wherein the pair of first bonding pads and the pair of second bonding pads have diameters equal to one another or different to one another. This exemplary embodiment or another exemplary embodiment may further include that the steps of effecting the at least one device to be connected with the first connection surface and effecting the at least another device to be connected with the second connection surface further includes: connecting the at least one device with a set of first conductors at the first connection surface and the at least another device with the set of first conductors at the second connection surface; and connecting the at least one device with a set of second conductors at the first connection surface and the at least another device with the set of second conductors at the second connection surface; wherein at least two conductors of the set of second conductors shield at least one conductor of the set of first conductors. This exemplary embodiment or another exemplary embodiment may further include that the steps of effecting the at least one device to be connected with the first connection surface and effecting the at least another device to be connected with the second connection surface further includes that the at least one device and the at least another device are free to connect with the first connection surface and the second connection surface at non-designated positions. This exemplary embodiment or another exemplary embodiment may further include that the step of enabling conductivity between the at least one device and the at least another device by the plurality of conductive pathways further includes that the plurality of conductive pathways provides electrical conductivity between the at least one device and the at least another device or thermally conductive between the at least one device and the at least another device to provide directional heat flow through the nonconductive matrix.

In yet another aspect, an exemplary embodiment of the present disclosure may provide a method. The method includes steps of: providing a preform having a predetermined profile; wrapping a plurality of conductors about an outer surface of the preform; injecting a nonconductive matrix between conductors of the plurality of conductors, wherein the nonconductive matrix permeates between interstitial spaces of the plurality of conductors to isolate some conductors of the plurality of conductors from one another; forming a batch product that includes the plurality of conductors and the nonconductive matrix; and wafering at least one section of the batch product to form at least one universal substrate, wherein the plurality of conductors of the at least one universal substrate defines a first connection surface, a second connection surface opposite to the first connection surface, and a plurality of conductive pathways defined between the first connection surface and the second connection surface.

This exemplary embodiment or another exemplary embodiment may further include that the plurality of conductors of the at least one universal substrate is one of electrically conductive between the first connection surface and the second connection surface to provide electrical communication between at least two devices and thermally conductive between the first connection surface and the second connection surface to provide directional heat flow through the at least one universal substrate between the at least two devices. This exemplary embodiment or another exemplary embodiment may further include that the step of wrapping the plurality of conductors further includes: wrapping the plurality of conductors in one of a uniform pattern or in a non-uniform pattern about the outer surface of the preform. This exemplary embodiment or another exemplary embodiment may further include that the step of wrapping the plurality of conductors further includes that each conductor of the plurality of conductors defines a diameter defined between a first connection end that defines a portion of the first connection surface and a second connection end that defines a portion of the second connection surface; wherein the diameter of each conductor of the plurality of conductors is equal to one another. This exemplary embodiment or another exemplary embodiment may further include that the step of wrapping the plurality of conductors further comprises: wrapping a first set of conductors of the plurality of conductors about the outer surface of the preform, wherein each conductor of the first set of conductors defines a first diameter defined between a first connection end that defines a portion of the first connection surface and a second connection end that defines a portion of the second connection surface; and wrapping a second set of conductors of the plurality of conductors about the outer surface of the preform, wherein each conductor of the second set of conductors defines a second diameter defined between a first connection end that defines a portion of the first connection surface and a second connection end that defines a portion of the second connection surface; wherein the second diameters of the second set of conductors are greater than the first diameters of the first set of conductors. This exemplary embodiment or another exemplary embodiment may further include engaging a pair of first bonding pads to first connections of a first set of conductors of the plurality of conductors of the at least one universal substrate and to second connections of the first set of conductors of the plurality of conductors of the at least one universal substrate; and engaging a pair of second bonding pads to first connections of a second set of conductors of the plurality of conductors of the at least one universal substrate and to second connections of the second set of conductors of the plurality of conductors of the at least one universal substrate; wherein the pair of first bonding pads and the pair of second bonding pads have diameters that are equal to one another or different from one another. This exemplary embodiment or another exemplary embodiment may further include encapsulating the at least one universal substrate with a passivation material; and removing sections of the passivation material from the at least one universal substrate prior to engaging the pair of first bonding pads and the pair of second bonding pads. This exemplary embodiment or another exemplary embodiment may further include effecting a set of first conductors of the plurality of conductors of the at least one universal substrate to be conductively engaged with a first electronic device of at least two devices at the first connection surface and a second electronic device of the at least two devices at the second connection surface; and effecting a set of second conductors of the plurality of conductors of the at least one universal substrate to be conductively disengaged from the at least two devices at the first connection surface and the second connection surface; wherein at least one conductor of the set of second conductors separates a first group of the set of first conductors and a second group of the set of first conductors from one another. This exemplary embodiment or another exemplary embodiment may further include effecting a set of first conductors of the plurality of conductors of the at least one universal substrate to be conductively engaged with a first electronic device of at least two devices at the first connection surface and a second electronic device of the at least two devices at the second connection surface; effecting a set of second conductors of the plurality of conductors of the at least one universal substrate to be conductivity disengaged from the at least two devices at the first connection surface and the second connection surface; and effecting a set of third conductors of the plurality of conductors of the at least one universal substrate to be conductively engaged with the first electronic device at the first connection surface and the second electronic device at the second connection surface; wherein at least two conductors of the set of third conductors shield at least one conductor of the set of first conductors. This exemplary embodiment or another exemplary embodiment may further include effecting at least one conductive tracing to be conductively engaged with at least one of the first connection surface and the second connection surface of the at least one universal substrate; wherein the at least one conductive tracing is adapted to provide conductivity between a first electronic device of the at least two devices and a second electronic device of the at least two devices that are non-coaxial with one another. This exemplary embodiment or another exemplary embodiment may further include wrapping a plurality of dielectric strands about the outer surface of the preform. This exemplary embodiment or another exemplary embodiment may further include that the step of the providing the preform having the predetermined profile further includes that the preform defines a rounded profile having a rounded outer surface; and wherein the step of wafering the at least one section of the batch product to form the at least one universal substrate further includes that the at least universal substrate defines a round configuration. This exemplary embodiment or another exemplary embodiment may further include effecting a first radiofrequency (RF) connection of the at least one universal substrate to be conductively engaged with a first RF device; and effecting a second radiofrequency (RF) connection of the at least one universal substrate to be conductively engaged with a second RF device. This exemplary embodiment or another exemplary embodiment may further include machining a third connection surface defined between the first connection surface and the second connection surface of the at least one universal substrate. This exemplary embodiment or another exemplary embodiment may further include effecting a set of first conductors of the plurality of conductors of the at least one universal substrate to be conductively engaged with a first electronic device at the first connection surface and a second electronic device at the second connection surface; and effecting a set of second conductors of the plurality of conductors of the at least one universal substrate to be conductively engaged with a third electronic device at the third connection surface and the second electronic device at the second connection surface; wherein the third electronic device is positioned between the first electronic device and the second electronic device. This exemplary embodiment or another exemplary embodiment may further include machining at least via defined between at least one set of conductors of the plurality of conductors and at least another set of conductors of the plurality of conductors. This exemplary embodiment or another exemplary embodiment may further include effecting the plurality of conductors of the at least one universal substrate to be conductively engaged with a first electronic device at the first connection surface and a second electronic device of the at least two devices at the second connection surface; and effecting a third electronic device to be disposed inside of the at least one universal substrate between the at least one set of conductors and the at least another set of conductors and be conductively engaged with the second electronic device; wherein the plurality of conductors of the at least one universal substrate is free from conductively engaging with the third electronic device. This exemplary embodiment or another exemplary embodiment may further include that the step of wafering the at least one section of the batch product to form at least one universal substrate further includes that a thickness of the at least one universal substrate is of at least 100 micrometers. This exemplary embodiment or another exemplary embodiment may further include a ratio of the plurality of conductors for the at least one universal substrate is greater than 10:1.

In yet another aspect, an exemplary embodiment of the present disclosure may provide a method. The method includes steps of: providing a preform having a predetermined profile; wrapping a plurality of conductors about an outer surface of the preform; injecting a nonconductive matrix between conductors of the plurality of conductors, wherein the nonconductive matrix permeates between interstitial spaces of the plurality of conductors to isolate some conductors of the plurality of conductors from one another; forming a batch product that includes the plurality of conductors and the nonconductive matrix; and wafering at least one section of the batch product to form at least one universal substrate, wherein the plurality of conductors of the at least one universal substrate defines a first connection surface, a second connection surface opposite to the first connection surface, and a plurality of conductive pathways defined between the first connection surface and the second connection surface; wherein the plurality of conductors of the at least one universal substrate is one of electrically conductive between the first connection surface and the second connection surface to provide electrical communication between at least two devices and thermally conductive between the first connection surface and the second connection surface to provide directional heat flow through the at least one universal substrate between the at least two devices.

### BRIEF DESCRIPTION OF THE DRAWINGS

Sample embodiments of the present disclosure are set forth in the following description, are shown in the drawings and are particularly and distinctly pointed out and set forth in the appended claims.

FIG. 1 illustrates a device-on-device product having a universal substrate interconnecting at least two devices with one another in accordance with one aspect of the present disclosure.

FIG. 2 illustrates a front, top, first isometric perspective view of the universal substrate in accordance with one aspect of the present disclosure.

FIG. 3 is a top plan view of the universal substrate shown in FIG. 1.

FIG. 3A is an enlargement of the highlighted region shown in FIG. 3.

FIG. 3B is a partial top plan view of an universal substrate in accordance with another aspect of the present disclosure

FIG. 4 is a longitudinal sectional view of the universal substrate taken in the direction of line 4-4 shown in FIG. 3.

FIG. 5 is a top plan view of the universal substrate that includes bonding pads.

FIG. 6 is a longitudinal sectional view of the universal substrate taken in the direction of line 6-6 shown in FIG. 5.

FIG. 7A is a longitudinal sectional view of the universal substrate that includes bonding pods and a surface passivation material.

FIG. 7B is a longitudinal sectional view of the universal substrate similar to FIG. 7A, but portions of the surface passivation material are removed to expose the bonding pads.

FIG. 8A is a diagrammatic view of at least one universal substrate interconnecting at least two devices with one another in accordance with another aspect of the present disclosure, wherein two solder connections connect with the at least one universal substrate and the at least two device.

FIG. 8B is a sectional view taken in the direction of line 8B-8B shown in FIG. 8A.

FIG. 9A is another diagrammatic view of at least one universal substrate interconnecting at least two devices with one another in accordance with another aspect of the present disclosure, wherein two solder connections and two shielding connection connect with the at least one universal substrate and the at least two device.

FIG. 9B is a sectional view taken in the direction of line 9B-9B shown in FIG. 9A.

FIG. 10 is another diagrammatic view of at least one universal substrate interconnecting at least two devices with one another in accordance with another aspect of the present disclosure, wherein two solder connections are offset from one another and connect with the at least one universal substrate and the at least two device and.

FIG. 11A is a diagrammatic view of at least one universal substrate interconnecting at least two devices with one another in accordance with another aspect of the present disclosure, wherein the at least one universal substrates includes sets of signal conductors and sets of unused conductors.

FIG. 11B is another diagrammatic view of at least one universal substrate interconnecting at least two devices with one another in accordance with another aspect of the present disclosure, wherein the at least one universal substrates includes sets of signal conductors, sets of unused conductors, and sets of ground conductors for shielding the sets of signal conductors.

FIG. 12 is another diagrammatic view of at least one universal substrate interconnecting at least three devices with one another in accordance with another aspect of the present disclosure, wherein the at least one universal substrate includes a stepped configuration for housing one of the three devices.

FIG. 13 is another diagrammatic view of at least one universal substrate interconnecting at least three devices with one another in accordance with another aspect of the present disclosure, wherein the at least one universal substrate includes a void for housing one of the three devices.

FIG. 14A is a fabrication process of fabricating a batch product, wherein a plurality of conductors are wound about a preform and a nonconductive matrix is applied to the plurality of conductors and the preform.

FIG. 14B is an enlargement of the highlighted region shown in FIG. 14A, wherein a section of the batch product is removed for further wafering processes.

FIG. 14C is an enlargement of the highlighted region shown in FIG. 14B, wherein the section of the batch product is wafered into a plurality of individual universal substrates.

FIG. 15A is another fabrication process of fabricating a batch product, wherein a plurality of conductors are wound about a preform and a nonconductive matrix is applied to the plurality of conductors and the preform.

FIG. 15B is an enlargement of the highlighted region shown in FIG. 15A, wherein a section of the batch product is removed for further wafering processes.

FIG. 16A is another fabrication process of fabricating a batch product, wherein a plurality of conductors and a set of blanks are wound about a preform and a nonconductive matrix is applied to the plurality of conductors, the set of blanks, and the preform.

FIG. 16B is an enlargement of the highlighted region shown in FIG. 16A, wherein a section of the batch product is removed for further wafering processes.

FIG. 16C is an enlargement of the highlighted region shown in FIG. 16B, wherein the section of the batch product is wafered into a plurality of individual universal substrates.

FIG. 17 is an exemplary method flowchart.

FIG. 18 in another exemplary method flowchart.

Similar numbers refer to similar parts throughout the drawings.

### DETAILED DESCRIPTION

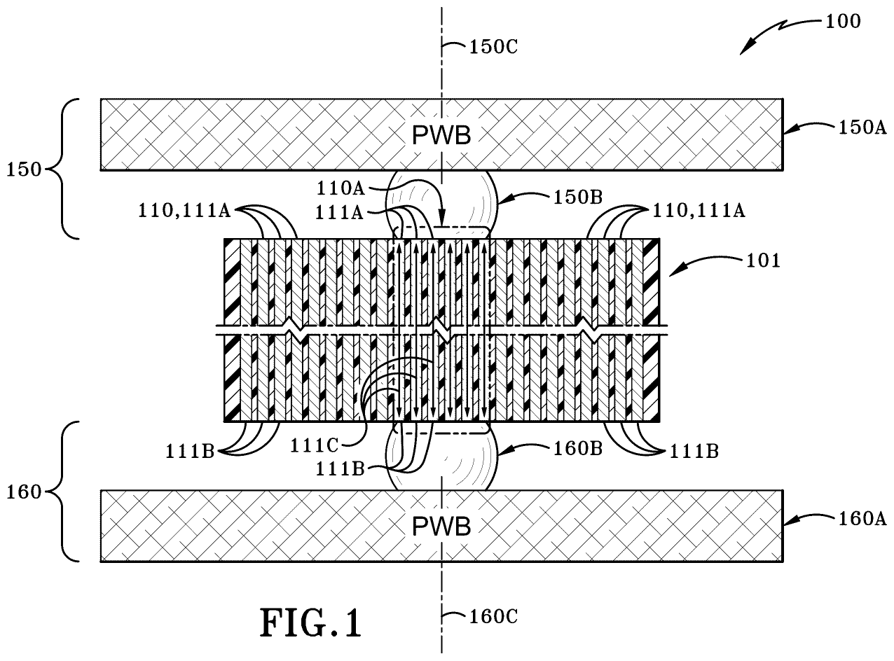

FIGS. 1-7B illustrate a universal substrate that is generally referred to as numeral 1. In the present disclosure, universal substrate 1 may be used operably engage at least one electronic device and at least another electronic device with one another to provided electrical communication between the at least one electronic device and the at least another electronic device. As discussed in greater detail below, universal substrate 1 enables at least one electronic device and at least another electronic device to be engaged with the universal substrate 1 at any location along the universal substrate 1 only if one or more electrical connections of the at least one electronic device and the at least another electronic device are vertically coaxially with one another. Such features and components of universal substrate is discussed in greater detail below.

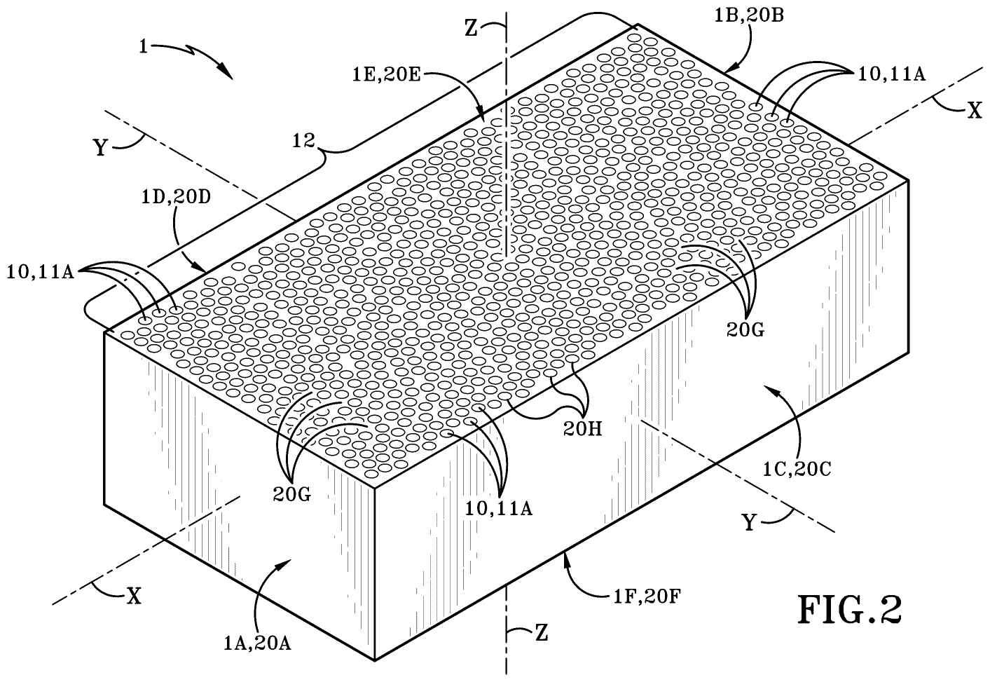

Referring to FIG. 2, universal substrate 1 may include a first end 1A, a second end 1B longitudinally opposite to the first end 1A, and a longitudinal axis (denoted by a dotted line labeled “X” in FIG. 1) defined therebetween. Universal substrate 1 may also include a first side 1C extending between the first end 1A and the second end 1B, a second side 1D extending between the first end 1A and the second end 1B and transversely opposite to the first side 1C, and a transverse axis (denoted by a dotted line labeled “Y” in FIG. 1) defined therebetween. Universal substrate 1 may also include a top end 1E positioned vertically above the first end 1A, the second end 1B, the first side 1C, and the second side 1D, a bottom end 1F positioned vertically below the first end 1A, the second end 1B, the first side 1C, and the second side 1D, and a vertical axis (denoted by a dotted line labeled “Z” in FIG. 1) defined therebetween.

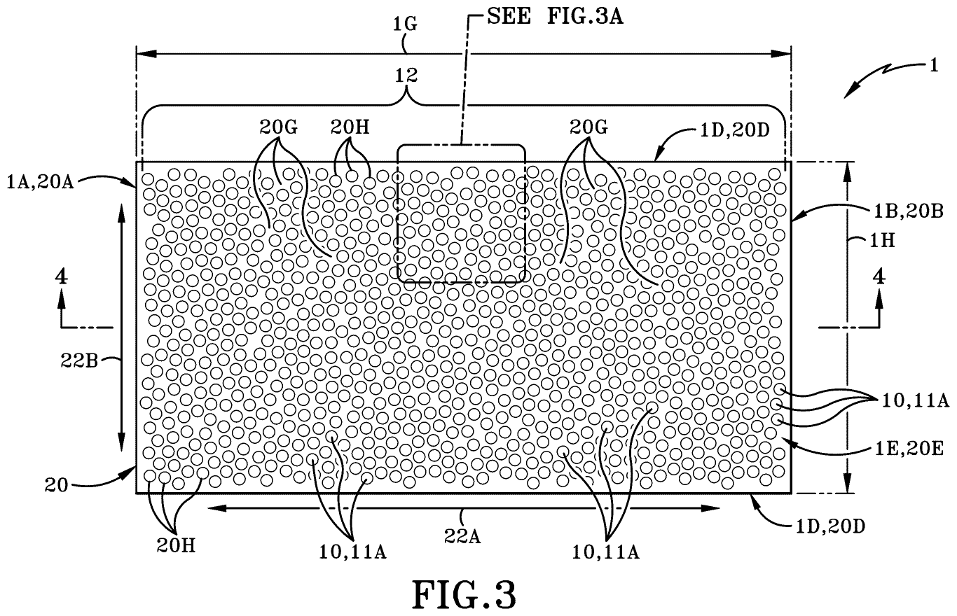

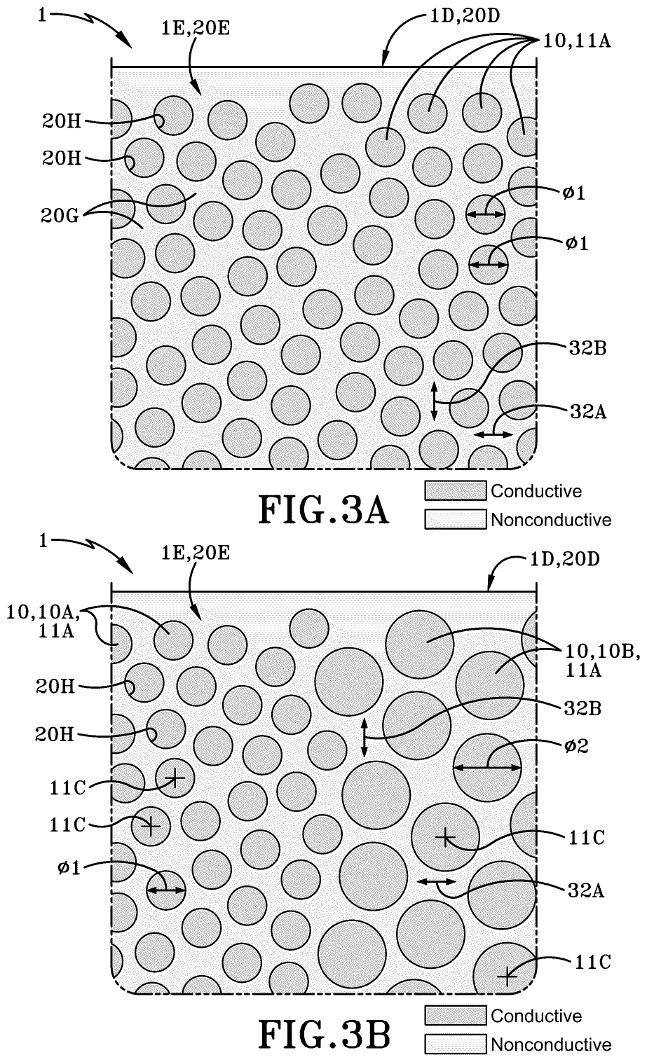

Still referring to universal substrate 1, universal substrate 1 also defines a length (denoted by a double arrow labeled “1G” in FIG. 3) that is measured between the first end 1A and the second end 1B. Universal substrate 1 also defines a width (denoted by a double arrow labeled “1H” in FIG. 1) that is measured between the first side 1C and the second side 1D. Universal substrate 1 also defines a height (denoted by a double arrow labeled “1J” in FIG. 3) that is measured between the top end 1E and the bottom end 1F. In the present disclosure, the height 1J is less than the length 1G and the width 1H. In other exemplary embodiment, universal substrate 1 may define any suitable length 1G, width 1H, and height 1J dictated by the implementation of universal substrate 1. In one exemplary embodiment, a height (or thickness) of a universal substrate may be at least 100 micrometers. In another exemplary embodiment, a height (or thickness) of a universal substrate may be between at least 100 micrometers up to about at least 1 millimeter.

Universal substrate 1 includes a plurality of conductors 10. As best seen in FIG. 3, each conductor of the plurality of conductors 10 includes a first connection end 11A that is positioned at the top end 1E of the universal substrate 1. Each conductor of the plurality of conductors 10 also includes a second connection end 11B that is positioned at the bottom end 1F of the universal substrate 1 and is vertically opposite to the first connection end 11A. Each conductor of the plurality of conductors 10 also includes a conductive pathway or axis 11C that extends between the first connection end 11A and the second connection end 11B. In one instance, the conductive pathway 11C of each conductor of the plurality of conductors 10 may provide electrical conductivity between the first connection end 11A and the second connection end 11B to enable electrical communication between at least two devices. In another instance, the conductive pathway 11C of each conductor of the plurality of conductors 10 may provide thermal conductivity between the first connection end 11A and the second connection end 11B to enable heat dissipation.

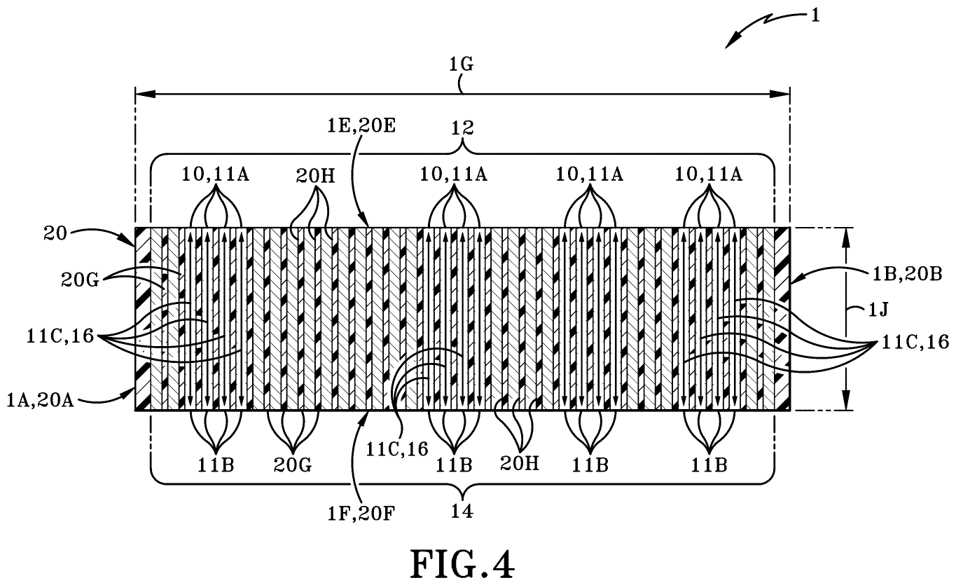

Still referring to the plurality of conductors 10, the plurality of conductors 11 collectively defines a first connection surface 12. As best seen in FIG. 4, the first connection surface 12 spans across the top end 1E of the universal substrate defined along the first connection ends 11A of the plurality of conductors 10. Similarly, the plurality of conductors 11 also collectively defines a second connection surface 14. As best seen in FIG. 4, the second connection surface 14 spans across the bottom end 1F of the universal substrate defined along the second connection ends 11B of the plurality of conductors 10. With such first connection surface 12 and second connection surface 14, a plurality of conductive pathways 16 is then defined between the first connection surface 12 and the second connection surface 14 by the plurality of conductors 10.

In the present disclosure, the plurality of conductors 10 are arranged in a randomized and/or non-uniform configuration. In other exemplary embodiments, a plurality of conductors may be arranged in any suitable configuration dictated by the implementation of the universal substrate 1. In one exemplary embodiment, a plurality of conductors may be arranged an organized and/or uniform configuration (i.e., aligned in distinct rows and/or columns). In one exemplary embodiment, at least one set of conductors of a plurality of conductors may be arranged an organized and/or uniform configuration, and at least another set of conductors of the plurality of conductors may be arranged a randomized and/or non-uniform configuration.

It should also be understood that one or more sets of conductors that are a part of the plurality of conductors 10 may define one or more diameters between respective first connection end 11A and second connection end 11B. In one example, and as best seen in FIG. 3A, each conductor of the plurality of conductors 10 defines a first diameter Ø1 that is continuous along the entire length of each conductor of the plurality of conductors 10 between the first connection end 11A and second connection end 11B. In another example, and as best seen in FIG. 3B, an alternative universal substrate 1′ includes a first set of conductors 10A′ and a second set of conductors 10B′ that are a part of the plurality of conductors 10. In this example, each conductor of the first set of conductors 10A′ defines a first diameter Ø1 that is continuous along the entire length of each conductor of the first set of conductors 10A′. In this same example, universal each conductor of the second set of conductors 10B′ defines a second diameter Ø2 that is continuous along the entire length of each conductor of the second set of conductors 10B′ where the second diameter Ø2 is greater than the first diameter Ø1. Such differing of diameters among the plurality of conductors 10 may be desirable when designers of device-on-device products have devices with different signal densities, and/or different sizes and/or footprints.

Universal substrate 1 also includes a nonconductive matrix or material 20 that operably engages with the plurality of conductors 10. As best seen in FIG. 2, nonconductive matrix 20 includes a first end 20A, a second end 20B longitudinally opposite to the first end 20A, and a longitudinal axis defined therebetween. Nonconductive matrix 20 may also include a first side 20C extending between the first end 20A and the second end 20B, a second side 20D extending between the first end 20A and the second end 20B and transversely opposite to the first side 20C, and a transverse axis defined therebetween. Nonconductive matrix 20 may also include a top engagement end or surface 20E positioned vertically above the first end 20A, the second end 20B, the first side 20C, and the second side 20D, a bottom engagement end or surface 20F positioned vertically below the first end 20A, the second end 20B, the first side 20C, and the second side 20D, and a vertical axis (denoted by a dotted defined therebetween.

Still referring to nonconductive matrix 20, nonconductive matrix 20 also includes a plurality of interior walls 20G defining a plurality of voids 20H. As best seen in FIG. 4, each interior wall of the plurality of interior walls 20G extends vertically between the top engagement end 20E and the bottom engagement end 20F defining a respective void of the plurality of voids 20H. In the present disclosure, each conductor of the plurality of conductors 10 operably engages with an interior wall of the plurality of interior walls 20G and is housed inside of a void of the plurality of voids 20H defined by the respective interior wall of the plurality of interior walls 20G. Such configuration between the plurality of conductors 10 and the plurality of interior walls 20G separates and/or insulates each conductors of the plurality of conductors 10 from one another to prevent conductivity along an axis that is perpendicular or orthogonal to the conductive pathway 11C of each conductor of the plurality of conductors 10; such nonconductive axis is discussed in greater detail below.

Still referring to nonconductive matrix 20, nonconductive matrix 20 includes a plurality of nonconductive pathways 22A, 22B. As best seen in FIG. 3A, each nonconductive pathway of the plurality of nonconductive pathways 22A, 22B extends longitudinally or transversely between each conductors of the plurality of conductors 10 to prevent any conductivity between adjacent conductors of the plurality of conductors 10. In one instance, a set of first nonconductive pathways 22A may extend between the first end 20A and the second end 20B to prevent any conductivity between adjacent conductors of the plurality of conductors 10 in a longitudinal direction. In another instance, a set of second nonconductive pathways 22B may extend between the first side 20C and the second side 20D to prevent any conductivity between adjacent conductors of the plurality of conductors 10 in a transverse direction.

By insulating each conductors of the plurality of conductors 10 from one another, each conductor of the plurality of conductors 10 are free from being conductive (either electrically or thermally) in a longitudinal direction or a transverse direction (i.e., along a nonconductive pathway of the plurality of nonconductive pathways 22). As such, universal substrate 1 is anisotropic by allowing conductivity (either electrical or thermal) in a first direction (i.e., conductive pathway 11C) while preventing conductivity (either electrical or thermal) in a second direction (i.e., nonconductive pathway 22) that is orthogonal to the first direction.

The structural configuration of the universal substrate 1 is considered advantageous at least because one or more electronic devices or products may be electrically connected at any position along the first connection surface 12 and the second connection surface 14 that is free from using any predetermined electrical voids or apertures formed into either the first connection surface 12 and the second connection surface 14. In the present disclosure, designers of device-on-device products are enabled to connect one or more devices (see FIGS. 1, 8A-8B, 9A, 11A, and 11) by using one or more conductors of the plurality of conductors 10 along the first connection surface 12 and the second connection surface 14. As such, designers of these device-on-device products are free to place devices at any location along the universal substrate 1 as desired without needing to initially create or define predetermined electrical voids or apertures in the universal substrate 1.

The structural configuration of the universal substrate 1 is considered advantageous at least because universal substrate 1 may be manufactured in various ways dictated by the machinery and/or tools available. In one example, universal substrates 1 may be manufactured individually (see FIG. 2) in a batch process. In another example, a single, monolithic universal substrate 1 may be manufactured in a continuous process where said monolithic universal substrate 1 is cut and/or divided into a plurality of universal substrates.

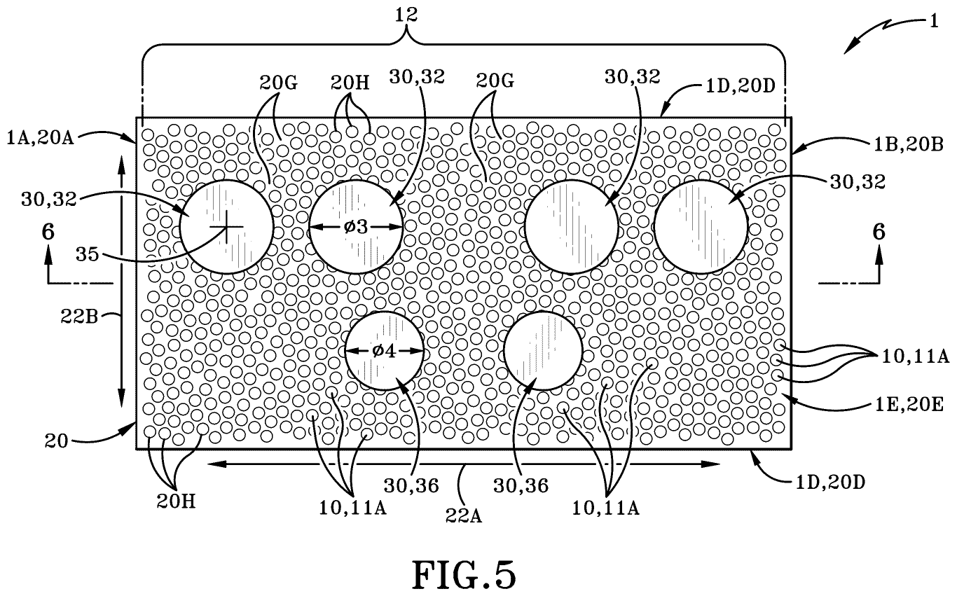

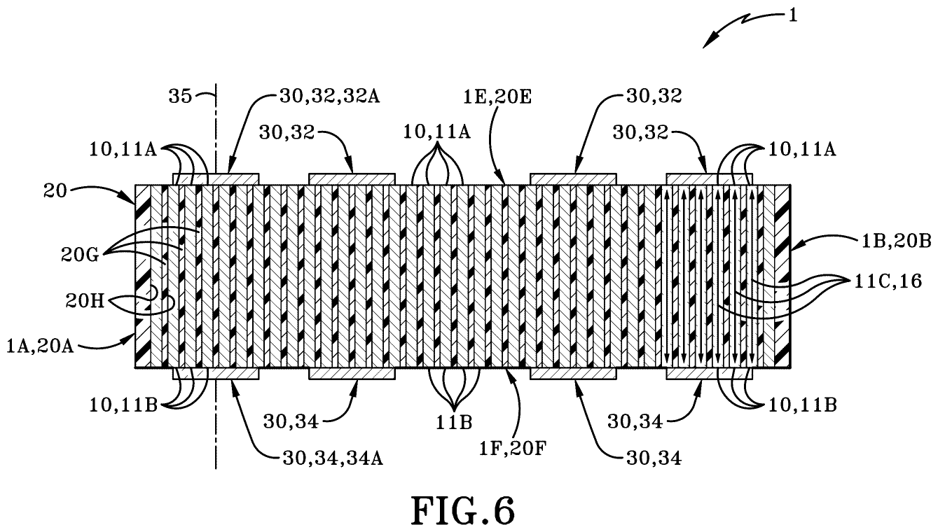

Universal substrate 1 may also include bonding pads 30 for enabling one or more devices to connect with the universal substrate 1. In the present disclosure, bonding pads 30 operably engage with one or more sets of conductors of the plurality of conductors 10. As best seen in FIGS. 5-7B, universal substrate 1 may include a first set of upper bonding pads 32 that operably engages with sets of conductors of the plurality of conductors 10 along the first connection surface 12. Still referring to FIGS. 5-7B, universal substrate 1 may also include a first set of lower bonding pads 34 that operably engages with the respective sets of conductors of the plurality of conductors 10 along the second connection surface 14. In this present disclosure, each upper bonding pad of the first set of bonding pads 32 is coaxially aligned with a respective lower bonding pad of the first set of bonding pads 34 by engaging with the same set of conductors of the plurality of conductors 10. As best seen in FIG. 6, an upper bonding pad 32A of the first set of bonding pads 32 is coaxially aligned with a respective lower bonding pad 34A of the first set of bonding pads 34 along a central axis 35 by connecting with a same set of conductors 10A of the plurality of conductors 10 such that the upper bonding pad 32A and the lower bonding pad 34A share conductive pathways 16A defined by the set of conductors 10A.

Referring to FIG. 5, each upper bonding pad of the first set of upper bonding pads 32 and each lower bonding pad of the first set of lower bonding pads 34 defines a third diameter Ø3. In the same embodiment, universal substrate 1 may also include a second set of upper bonding pads 36 that operably engages with sets of conductors of the plurality of conductors 10 along the first connection surface 12; each upper bonding pad of the second set of upper bonding pads 36 defines a fourth diameter Ø4 that is less than the third diameters Ø2 of each upper bonding pad of the first set of upper bonding pads 32 and of each lower bonding pad of the first set of lower bonding pads 34. Universal substrate 1 may also include a second set of lower bonding pads (not illustrated) that operably engages with the respective sets of conductors of the plurality of conductors 10 along the second connection surface 14 and is coaxial with the second set of upper bonding pads 36; each lower bonding pad of the second set of lower bonding pads would also define the fourth diameter Ø4 that is less than the third diameters Ø3 of each upper bonding pad of the first set of upper bonding pads 32 and of each lower bonding pad of the first set of lower bonding pads 34.

It should be appreciated that universal substrate 1 may include any bonding pad 30 discussed and illustrated herein and other commercially available bonding pads to enable designers of device-on-device products to connect various sizes of devices with the universal substrate 1 based on various reasons, including the signal density of the device and the overall size and/or footprint of the device. In one example, universal substrate 1 may include the combination of the first set of upper bonding pads 32 and the first set of lower bonding pads 34 or combination of the second set of upper bonding pads 36 and the second set of lower bonding pads 38. In another example, universal substrate 1 may include the combination of the first set of upper bonding pads 32 and the first set of lower bonding pads 34 and the combination of the second set of upper bonding pads 36 and the second set of lower bonding pads. In yet another example, universal substrate 1 may omit the combination of the first set of upper bonding pads 32 and the first set of lower bonding pads 34 and the combination of the second set of upper bonding pads 36 and the second set of lower bonding pads.

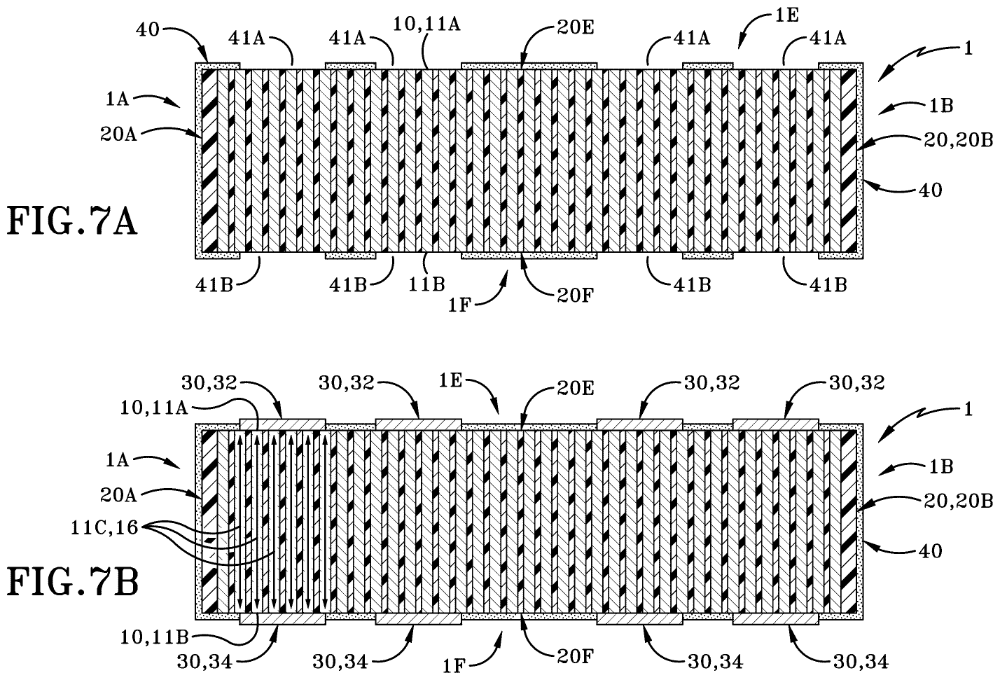

Universal substrate 1 may also include a surface passivation material 40. As best seen FIGS. 7A-7B, surface passivation material 40 may completely surround and encapsulate the plurality of conductors 10 and the nonconductive matrix 20 to prevent unwanted bonds or defects from interfering with connections between the plurality of conductors 10 and one or more devices. In this particular embodiment, portions of the surface passivation material 40 may be removed to enable adhesion of bonding pads 30 with the plurality of conductors 10. As best seen in FIG. 7A, upper holes 41A and lower holes 41B may be defined in the surface passivation material 40 to enable adhesion of bonding pads 30 with the conductors 10. Such encapsulation of the bonding pads 30 by the surface passivation material 40 may prevent unwanted bonds or defects from interfering with connections between the plurality of conductors 10, the bonding pads 30, and one or more devices creating a device-on-device.

When surface passivation material 40 is included with universal substrate 1, other various components may be operably engaged with the universal substrate. In one instance, conductive traces and similar components of the like may be applied to universal substrate 1 from one bonding pad (e.g., one or more bonding pads of the first set of upper bonding pads 32, the first set of lower bonding pads 34, the second set of upper bonding pads 36, and/or the second set of lower bonding pads 38) to build an additive circuit. In another instance, a redistribution layer (RDL) or other similar additive circuitry may be included to provide additional interconnects in universal substrate 1 as a vertical interconnect (i.e., along the vertical axis “Z”) in a fan out wafer level.

Having now described the components and features of universal substrate 1, various methods and implementations of using universal substrate 1 with electronic devices to build device-on-device products are described in greater detail below. It should be understood that the following methods and implementations of using universal substrate 1 should not limit the use of universal substrate 1.

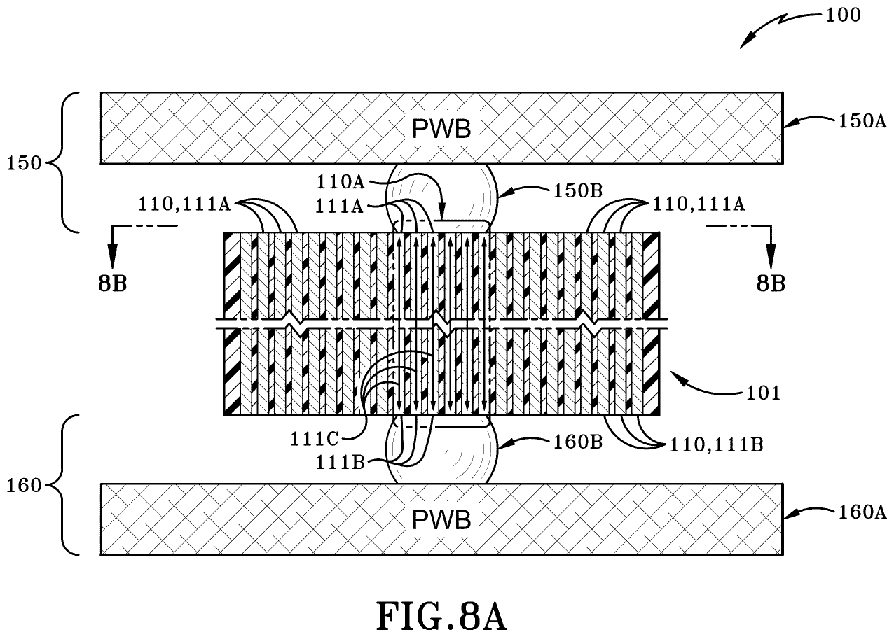

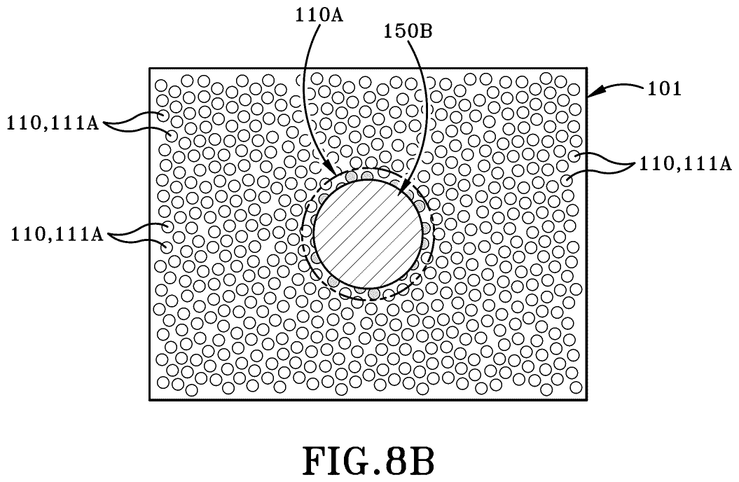

In one example, a device-on-device 100 may include a universal substrate 101 (identical to universal substrate 1) that is used to interconnect at least two electronic devices with one another via solder ball connections. As best seen in FIGS. 1 and 8A-8B, universal substrate 101 is used to interconnect a first electronic device 150 and a second electronic device 160 with one another, via the plurality of conductors 110, to provide electrical conductivity or thermal conductivity.

In this example, first electronic device 150 includes at least a printed wiring board (PWB) or printed circuit board (PCB) 150A that operably engages with at least one solder ball connection 150B having a first central axis 150C. While not illustrated herein, additional electrical components and/or parts (e.g., dies, wire bonds, etc.) may be operably engaged with PWB 150A to form the first electronic device 150. Similarly, second electronic device 160 includes at least a PWB or PCB 160A that operably engages with at least another solder ball connection 160B having a second central axis 160C that is coaxial with the first central axis 150C. While not illustrated herein, additional electrical components and/or parts (e.g., dies, wire bonds, etc.) may be operably engaged with PWB 160A to form the second electronic device 160.

In this example, at least one set of conductors 110A of the plurality of conductors 110 may operably engage with the at least one solder ball connection 150B of the first electronic device 150 and the at least another solder ball connection 160B of the second electronic device 160. In this instance, the at least one solder ball connection 150B operably engages with first connection end 111A of the at least one set of conductors 110A, and the at least another solder ball connection 160B operably engages with a second connection end 111B of the at least one set of conductors 110A. In this instance, the at least one solder ball connection 150B of the first electronic device 150 and the at least another solder ball connection 160B of the second electronic device 160 are also coaxial with one another such that the at least one solder ball connection 150B and the at least another solder ball connection 160B are conductive along conductive pathways 111C of the at least one set of conductors 110A.

In other exemplary embodiments, other conductive connections may be used with device-on-device 100 for interconnecting at least two electronic devices with one another. Examples of suitable conductive connections that may be used with a device-on-device product for interconnecting at least two electronic devices with one another include wire bonds, thermosonic bonds, gold stud bumps, conductive adhesives, and other suitable conductive connections that may be used with a device-on-device product for interconnecting at least two electronic devices with one another.

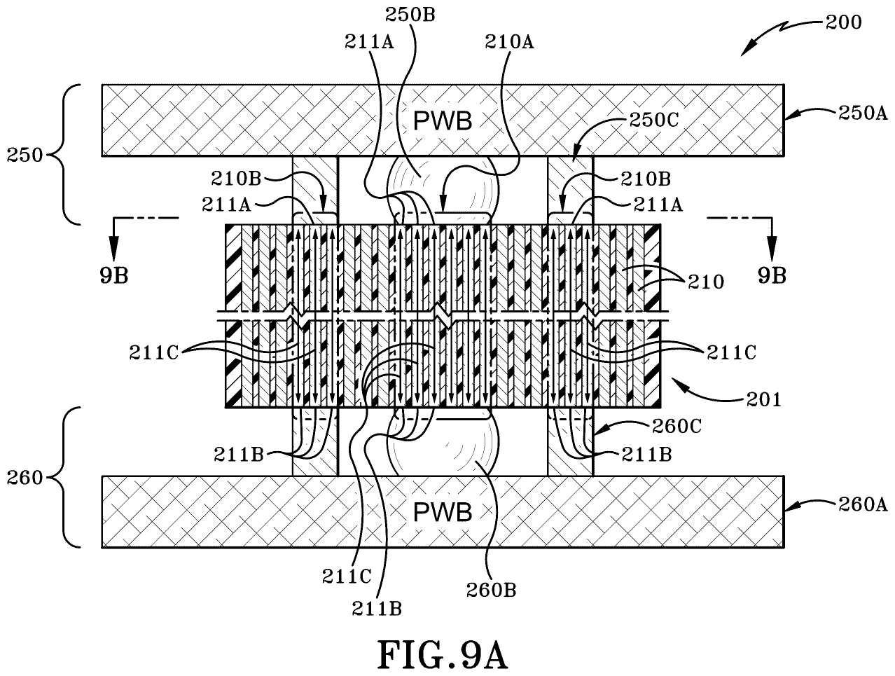

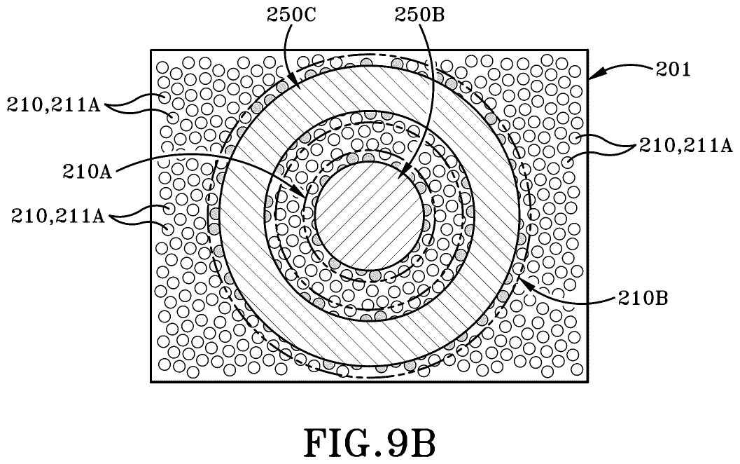

In another example, another device-on-device 200 may include a universal substrate 201 (identical to universal substrate 1) that is used to interconnect at least two electronic devices with one another via solder ball connections and shielding connections. As best seen in FIGS. 9A-9B, universal substrate 201 is used to interconnect a first electronic device 250 and a second electronic device 260 with one another, via the plurality of conductors 210, to provide electrical conductivity or thermal conductivity.

In this example, first electronic device 250 includes at least a printed wiring board (PWB) or printed circuit board (PCB) 250A that operably engages with at least one solder ball connection 250B and at least one shielding connection 250C. While not illustrated herein, additional electrical components and/or parts (e.g., dies, wire bonds, etc.) may be operably engaged with PWB 250A to form the first electronic device 250. Similarly, second electronic device 260 includes at least a PWB or PCB 260A that operably engages with at least another solder ball connection 260B and at least one shielding connection 260C. While not illustrated herein, additional electrical components and/or parts (e.g., dies, wire bonds, etc.) may be operably engaged with PWB 260A to form the second electronic device 260.

In this same example, at least one set of conductors 210A of the plurality of conductors 210 may operably engage with the at least one solder ball connection 250B of the first electronic device 250 and the at least another solder ball connection 260B of the second electronic device 260. In this instance, the at least one solder ball connection 250B operably engages with first connection ends 211A of the at least one set of conductors 210A, and the at least another solder ball connection 260B operably engages with second connection ends 211B of the at least one set of conductors 210A. In this instance, the at least one solder ball connection 250B of the first electronic device 250 and the at least another solder ball connection 260B of the second electronic device 260 are also coaxial with one another such that the at least one solder ball connection 250B and the at least another solder ball connection 260B are conductive along conductive pathways 211C of the at least one set of conductors 210A.

In this same example, at least another set of conductors 210B of the plurality of conductors 210 may operably engage with the at least one shielding connection 250C of the first electronic device 250 and the at least another shielding connection 260C of the second electronic device 260. In this instance, the at least one shielding connection 250C operably engages with first connection ends 211A of the at least another set of conductors 210B, and the at least another shielding connection 260C operably engages with second connection ends 211B of the at least another set of conductors 210B. In this instance, the at least one shielding connection 250C of the first electronic device 250 and the at least another shielding connection 260C of the second electronic device 260 are also coaxial with one another such that the at least one shielding connection 250C and the at least another shielding connection 260C are conductive along conductive pathways 211C of the at least another set of conductors 210B. Upon engagement, the at least one shielding connection 250C and the at least another shielding connection 260C electrically shield and/or isolate the at least one solder ball connection 250B and the at least another solder ball connection 260B from unwanted and/or incidental electrical charge surrounding the device-on-device device 200.

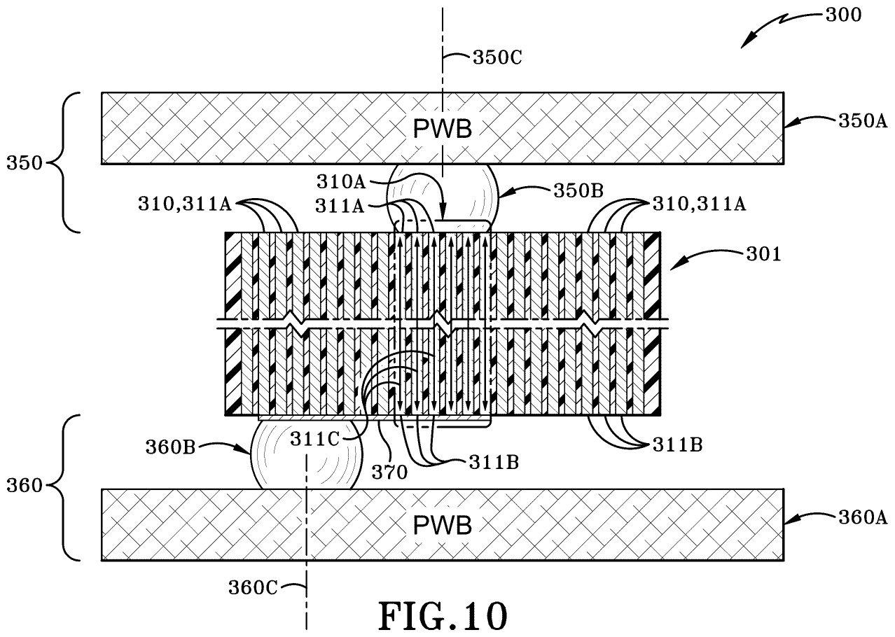

In yet another example, another device-on-device 300 may include a universal substrate 301 (identical to universal substrate 1) that is used to interconnect at least two devices with one another via solder ball connections and at least one conductive tracing element. As best seen in FIG. 10, universal substrate 301 is used to interconnect a first electronic device 350 and a second electronic device 360 with one another, via the plurality of conductors 310, to provide electrical conductivity or thermal conductivity.

In this example, first electronic device 350 includes at least a printed wiring board (PWB) or printed circuit board (PCB) 350A that operably engages with at least one solder ball connection 350B having a first central axis 350C. While not illustrated herein, additional electrical components and/or parts (e.g., dies, wire bonds, etc.) may be operably engaged with PWB 350A to form the first electronic device 350. Similarly, second electronic device 360 includes at least a PWB or PCB 360A that operably engages with at least another solder ball connection 360B having a second central axis 360C that is offset from the first central axis 350C. While not illustrated herein, additional electrical components and/or parts (e.g., dies, wire bonds, etc.) may be operably engaged with PWB 360A to form the second electronic device 360.

In this example, at least one set of conductors 310A of the plurality of conductors 310 may operably engage with the at least one solder ball connection 350B of the first electronic device 350 and the at least another solder ball connection 360B of the second electronic device 360. However, in this example, a conductive tracing element 370 is used to connect the at least another solder ball connection 360B with the at least one solder ball connection 350B due to the at least another solder ball connection 360B being offset from the at least one solder ball connection 350B based on the first and second central axes 350C, 360C. In this instance, the at least one solder ball connection 350B operably engages with first connection ends 311A of the at least one set of conductors 310A, and the at least another solder ball connection 360B operably engages with second connection ends 311B of the at least one set of conductors 310A via the conductive tracing element 370. In this instance, the conductive tracing element 370 enables the at least one solder ball connection 350B of the first electronic device 350 and the at least another solder ball connection 360B of the second electronic device 360 to be coaxial with one another such that the at least one solder ball connection 350B and the at least another solder ball connection 360B are conductive along conductive pathways 311C of the at least one set of conductors 310A.

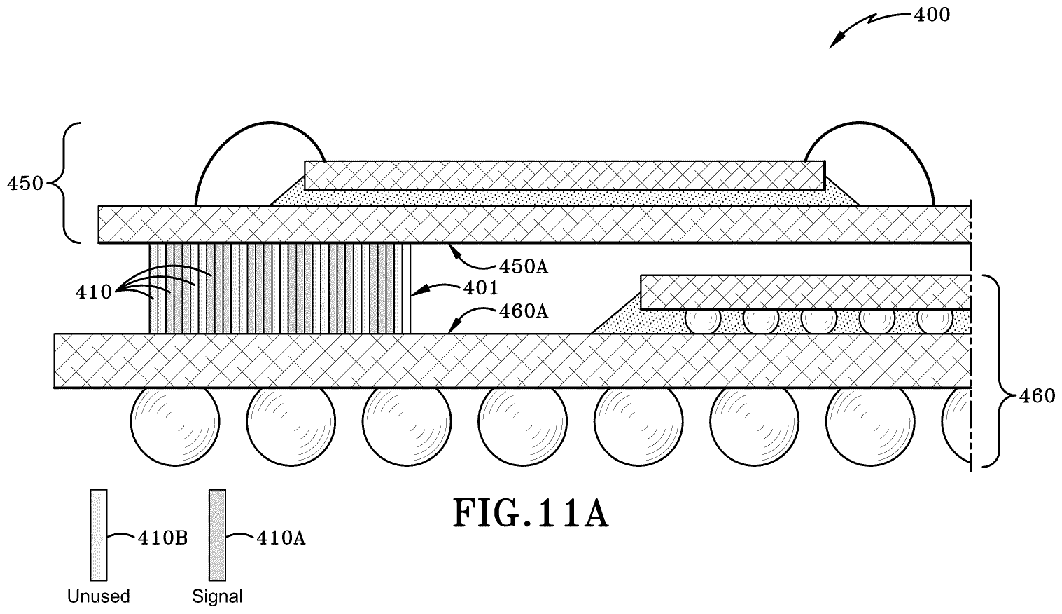

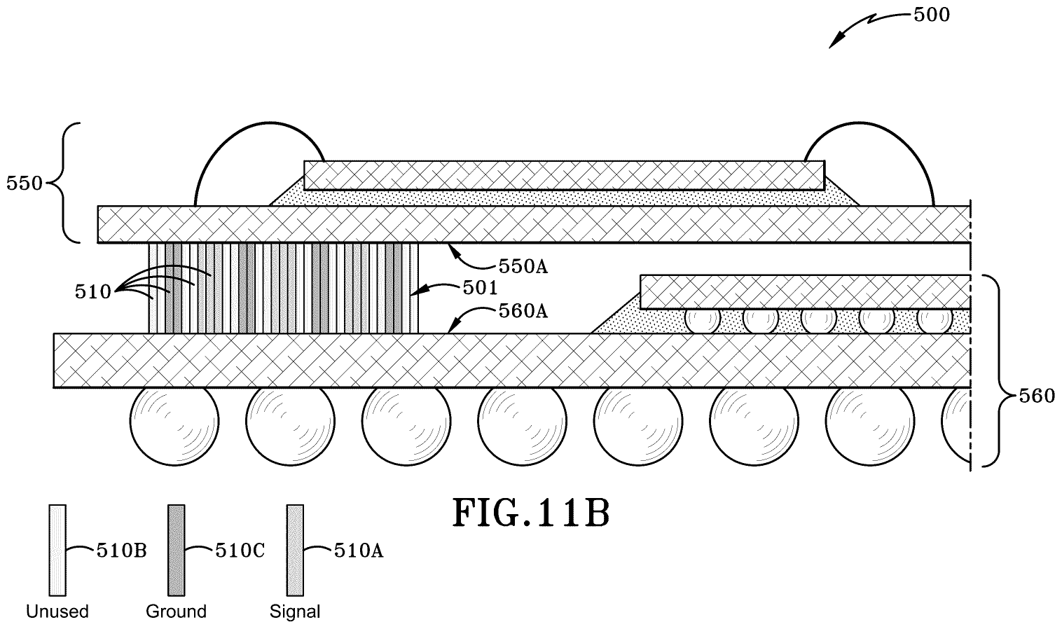

In yet another example, another device-on-device 400 may include a universal substrate 401 (identical to universal substrate 1) that is used to interconnect at least two devices with one another. As best seen in FIG. 11A, universal substrate 401 is used to interconnect a first electronic device 450 and a second electronic device 460 with one another, via the plurality of conductors 410, to provide either electrical conductivity or thermal conductivity. In the illustrated embodiment, universal substrate 401 includes sets of first or signal conductors 410A that are used to direct and send electrical signals between a first set of connections 450A of the first electronic device 450 and a second set of connections 460A of the second electronic device 460 for electrical conductivity. In the same embodiment, universal substrate 401 also includes sets of second or unused conductors 410B that are free from being used to direct and send electrical signals between the first electronic device 450 and the second electronic device 460 based on the first set of connections 450A and the second set of connections 460A.

In this example, each set of the signal conductors 410A utilizes at least three conductors to direct and send electrical signals between the first set of connections 450A of the first electronic device 450 and the second set of connections 460A of the second electronic device 460 for electrical conductivity. While three conductors are being used in each set of the signal conductors 410A to provide electrical conductivity between the first electronic device 450 and the second electronic device 460, any suitable number of conductors may be included in each set of signal conductors 410A as dictated by the implementation of universal substrate 401, including the signal density of each device, the overall size and/or footprint of each device, and other factors of each device needed to provide electrical conductivity or thermal conductivity.

In yet another example, another device-on-device 500 may include a universal substrate 501 (identical to universal substrate 1) that is used to interconnect a first electronic device 550 and a second electronic device 560 with one another, similar to universal substrate 401, to provide either electrical conductivity or thermal conductivity by a plurality of conductors 510 (see FIG. 11B). Similar to universal substrate 401, universal substrate 501 includes sets of first or signal conductors 510A that are used to direct and send electrical signals between a first set of connections 550A of the first electronic device 550 and the second set of connections 560A of the second electronic device 560 for electrical conductivity. Similar to universal substrate 401, universal substrate 501 also includes sets of second or unused conductors 510B that are free from being used to direct and send electrical signals between the first electronic device 550 and the second electronic device 560 based on the first set of connections 550A and the second set of connections 560A.

However, in this illustrated embodiment, universal substrate 501 also include sets of third or ground conductors 510C that are used to ground electrical conductivity between the first set of connections 550A of the first electronic device 550 and the second set of connections 560A of the second electronic device 560. In this alternative example, the sets of ground conductors 510C surround and/or encapsulate the sets of signal conductors 510A to prevent unwanted and/or undesired electrical conductivity with the sets of signal conductors 510A. As such, the plurality of conductors 510C provided in this universal substrate 501 may be used for both directing and sending electrical signals between at least two devices and grounding the at least two devices.

In this example, each set of the signal conductors 510A utilizes at least three conductors to direct and send electrical signals between the first set of connections 550A of the first electronic device 550 and the second set of connections 560A of the second electronic device 560 for electrical conductivity. While three conductors are being used in each set of the signal conductors 510A to provide electrical conductivity between the first electronic device 550 and the second electronic device 560, any suitable number of conductors may be included in each set of signal conductors 510A as dictated by the implementation of universal substrate 501, including the signal density of each device, the overall size and/or footprint of each device, and other factors of each device needed to provide electrical conductivity or thermal conductivity.

In this example, each set of the ground conductors 510C utilizes at least two conductors to ground electrical conductivity between the first set of connections 550A of the first electronic device 550 and the second set of connections 560A of the second electronic device 560. While two conductors are being used in each set of the ground conductors 510C to ground electrical conductivity between the first electronic device 550 and the second electronic device 560, any suitable number of conductors may be included in each set of ground conductors 510C as dictated by the implementation of universal substrate 501, including the signal density of each device, the overall size and/or footprint of each device, and other factors of each device needed to ground electrical conductivity or thermal conductivity.

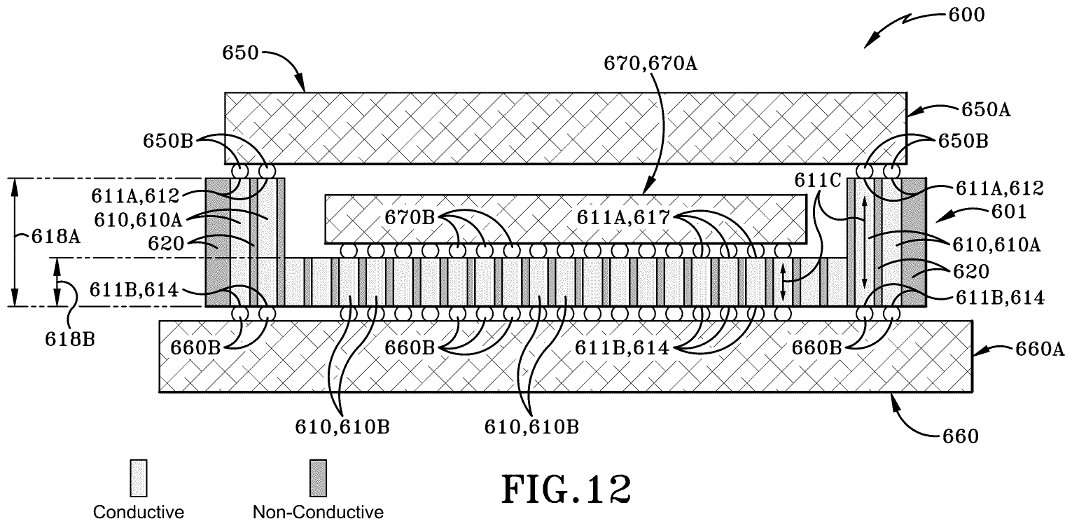

In yet another example, FIG. 12 illustrates another device-on-device 600 may include a universal substrate 601 that is used to interconnect at least two devices with one another. Universal substrate 601 is similar to universal substrate 1 discussed above and illustrated in FIGS. 1-4, except as detailed below.

In this embodiment, universal substrate 601 includes a plurality of conductors 610. As best seen in FIG. 12, and similar to universal substrate 1, each conductor of the plurality of conductors 610 includes a first connection end 611A, a second connection end 611B that is vertically opposite to the first connection end 611A, and a conductive pathway or axis 611C that extends between the first connection end 611A and the second connection end 611B. In one instance, the conductive pathway 611C of each conductor of the plurality of conductors 610 may provide electrical conductivity between the first connection end 611A and the second connection end 611B to enable electrical communication between at least two devices. In another instance, the conductive pathway 611C of each conductor of the plurality of conductors 610 may provide thermal conductivity between the first connection end 611A and the second connection end 611B to enable heat dissipation.

Still referring to the plurality of conductors 610, the plurality of conductors 611 also collectively defines a first connection surface 612. As best seen in FIG. 12, the first connection surface 612 spans across a top end of the universal substrate 601 and is defined along the first connection ends 611A of the plurality of conductors 610. Similarly, the plurality of conductors 611 also collectively defines a second connection surface 614. As best seen in FIG. 12, the second connection surface 614 spans across a bottom end of the universal substrate 601 and is defined along the second connection ends 611B of the plurality of conductors 610. With such first connection surface 612 and second connection surface 614, a plurality of conductive pathways is then defined between the first connection surface 612 and the second connection surface 614 by the plurality of conductors 610.

In this embodiment, however, universal substrate 601 includes a first bundle or set of conductors 610A and a second bundle of set of conductors 610B that having varying heights. As best seen in FIG. 12, each conductor of the first set of conductors 610A defines a first height 618A that extends between the first connection end 611A and the second connection end 611B. Still referring to FIG. 12, each conductor of the second set of conductors 610B defines a second height 618B that extends between the first connection end 611A and the second connection end 611B. In the illustrated embodiment, the first height 618A of each conductor of the first set of conductors 610A is greater than the second height 618B of each conductor of the second set of conductors 610B. With such variance in height, the second set of conductors 610B also defines a third connection surface 617 along the first connections end 611A of the second set of conductors 610B. In the illustrated embodiment, the third connection surface 617 is defined between the first connection surface 612 and the second connection surface 614 to provide a stepped and/or mezzanine configuration for device-on-device packages, which is discussed in greater detail below.

Universal substrate 601 also includes a nonconductive matrix or dielectric material 620 that surrounds each conductor of the plurality of conductors 610. Similar to nonconductive material 20, the nonconductive matrix 620 surrounds and isolates each conductor of the plurality of conductors 610 to prevent electrical conductivity and thermal conductivity between adjacent conductors of the plurality of conductors in either a longitudinal direction or a lateral direction.

It should be understood that commercially-available tools and/or equipment may be used to machine and/or form various features into universal substrate 601. In one exemplary embodiment, commercially-available tools and/or equipment may be used to machine linear, non-linear, and/or stepped profiles into the universal substrate 601. In another exemplary embodiment, tools and/or equipment may be used to remove one or more conductors 610 and nonconductive matrix 620 from universal substrate 601 to create linear, non-linear, and/or stepped profiles into the universal substrate 601.

Still referring to FIG. 12, universal substrate 601 is used to interconnect a first electronic device 650 and a second electronic device 660 with one another, via the plurality of conductors 610, to provide either electrical conductivity or thermal conductivity. Universal substrate 601 is also used to interconnect the second electronic device 660 and a third electronic device 670 with one another, via the plurality of conductors 610, to provide either electrical conductivity or thermal conductivity

In the illustrated embodiment, the first set of conductors 610A are used to direct and send electrical signals between a printed wiring board (PWB) or printed circuit board (PCB) 650A, via solder ball connections 650B, of the first electronic device 650 and a printed wiring board (PWB) or printed circuit board (PCB) 660A, via solder ball connections 660B, of the second electronic device 660 for electrical conductivity. In the same embodiment, the second set of conductors 610B are used to direct and send electrical signals between a printed wiring board (PWB) or printed circuit board (PCB) 670A, via solder ball connections 670B, of the third electronic device 670 and the PWB 660A, via the solder ball connections 660B, of the second electronic device 660 for electrical conductivity. Such configuration of the universal substrate 601 shortens and/or reduces the overall height and/or footprint of device-on-device product 600 to enable smaller and/or compact device-on-device products.

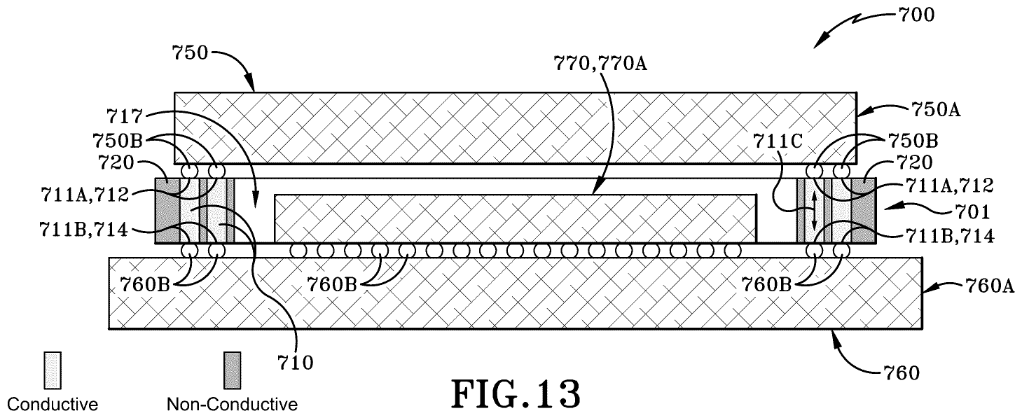

In yet another example, FIG. 13 illustrates another device-on-device 700 may include a universal substrate 701 that is used to interconnect at least two devices with one another. Universal substrate 701 is similar to universal substrate 1 discussed above and illustrated in FIGS. 1-4, except as detailed below.

In this embodiment, universal substrate 701 includes a plurality of conductors 710. As best seen in FIG. 13, and similar to universal substrate 1, each conductor of the plurality of conductors 710 includes a first connection end 711A, a second connection end 711B that is vertically opposite to the first connection end 711A, and a conductive pathway or axis 711C that extends between the first connection end 711A and the second connection end 711B. In one instance, the conductive pathway 711C of each conductor of the plurality of conductors 710 may provide electrical conductivity between the first connection end 711A and the second connection end 711B to enable electrical communication between at least two devices. In another instance, the conductive pathway 711C of each conductor of the plurality of conductors 710 may provide thermal conductivity between the first connection end 711A and the second connection end 711B to enable heat dissipation.

Still referring to the plurality of conductors 710, the plurality of conductors 711 also collectively defines a first connection surface 712. As best seen in FIG. 13, the first connection surface 712 spans across a top end of the universal substrate 701 and is defined along the first connection ends 711A of the plurality of conductors 710. Similarly, the plurality of conductors 711 also collectively defines a second connection surface 714. As best seen in FIG. 13, the second connection surface 714 spans across a bottom end of the universal substrate 701 and is defined along the second connection ends 711B of the plurality of conductors 710. With such first connection surface 712 and second connection surface 714, a plurality of conductive pathways is then defined between the first connection surface 712 and the second connection surface 714 by the plurality of conductors 710.

In this embodiment, however, universal substrate 701 defines at least one via or void 717 between at least two bundles or sets of conductors 710A, 710B of the plurality of conductors. While universal substrate 701 defines a single void 717 between two sets of conductors 710A, 710B of the plurality of conductors 710, universal substrate 701 may define any suitable number of vias or voids between at least two sets of conductors (e.g., sets of conductors 710A, 710B) of a plurality of conductors 710.

Universal substrate 701 also includes a nonconductive matrix or dielectric material 720 that surrounds each conductor of the plurality of conductors 710. Similar to nonconductive material 20, the nonconductive matrix 720 surrounds and isolates each conductor of the plurality of conductors 710 to prevent electrical conductivity and thermal conductivity between adjacent conductors of the plurality of conductors in either a longitudinal direction or a lateral direction.

It should be understood that commercially-available tools and/or equipment may be used to machine and/or form various features into universal substrate 701. In one exemplary embodiment, commercially-available tools and/or equipment may be used to machine linear, non-linear, and/or other profiles into the universal substrate 701. In another exemplary embodiment, tools and/or equipment may be used to remove one or more conductors 610 and nonconductive matrix 620 from universal substrate 601 to create linear, non-linear, and/or stepped profiles into the universal substrate 601.

Still referring to FIG. 13, universal substrate 701 is used to interconnect a first electronic device 750 and a second electronic device 760 with one another, via the plurality of conductors 710, to provide either electrical conductivity or thermal conductivity. Universal substrate 701 is also configured to interconnect the second electronic device 660 and a third electronic device 670 with one another to enable either electrical conductivity or thermal conductivity without engaging the second electronic device 660 or the third electronic device 670

In the illustrated embodiment, the at least two sets of conductors 710A, 710B are used to direct and send electrical signals between a printed wiring board (PWB) or printed circuit board (PCB) 750A, via solder ball connections 750B, of the first electronic device 750 and a printed wiring board (PWB) or printed circuit board (PCB) 760A, via solder ball connections 760B, of the second electronic device 760 for electrical conductivity. In the same embodiment, the at least two sets of conductors 710A, 710B are free from engaging and/or connecting with the third electronic device 770 to allow electrical signals to be directed and sent between a printed wiring board (PWB) or printed circuit board (PCB) 770A, via solder ball connections 770B, of the third electronic device 770 and the PWB 760A, via the solder ball connections 760B, of the second electronic device 760 for electrical conductivity. Such configuration of the universal substrate 701 shortens and/or reduces the overall height and/or footprint of device-on-device product 700 to enable smaller and/or compact device-on-device products.

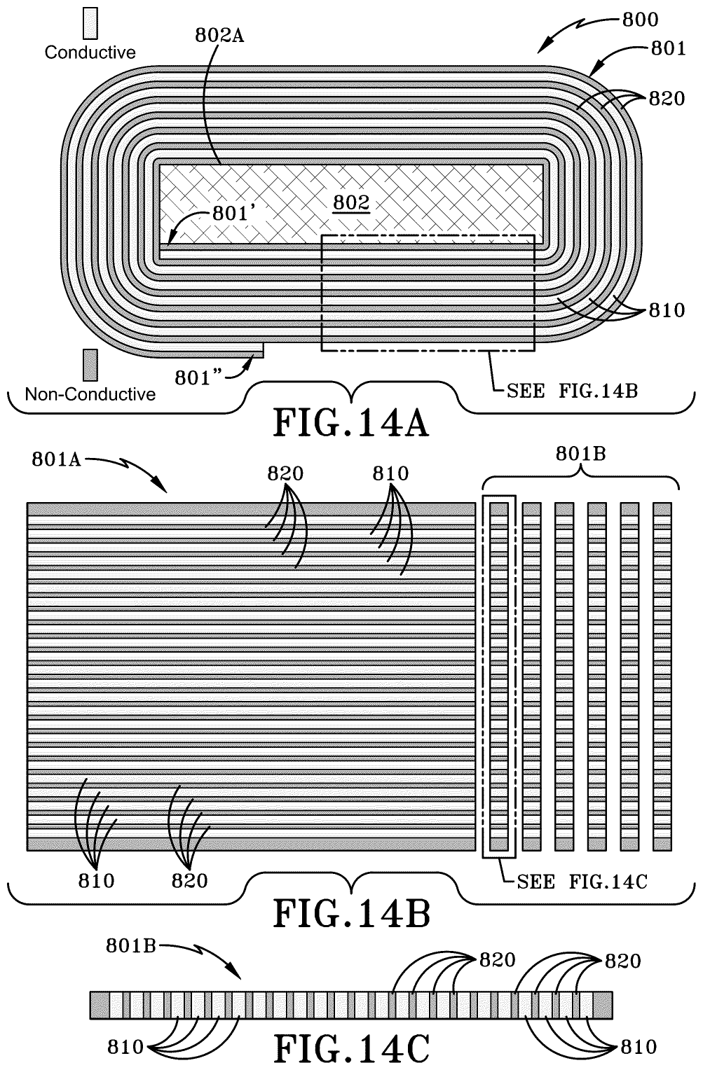

FIGS. 14A-14C illustrate a fabrication process 800 for creating a batch product 801 that may be wafered into one or more universal substrates described and illustrated herein (e.g., universal substrate 1). Such components of the used in fabricating a batch product 801 for the fabrication process 800 are discussed in greater detail below.

Initially, a preform or template 802 that defines a predetermined and/or desired outer profile for fabricating a batch universal product 801 (hereinafter “batch product”) that may be wafered into one or more universal substrates described and illustrated herein (similar to universal substrate 1). As best seen in FIG. 14A, the preform 802 includes an outer surface 802A that is continuous along the entire length of the preform 802 for holding one or more conductors of a batch product 801, which is discussed in greater detail below. In the present disclosure, a first end 801′ of the batch product 801 is engaged with the outer surface 802A of the perform 802, and a second end 801″ of the batch product 801 is opposite to the first end 801′ and is spaced apart from the perform 802 due to the batch product 801 being wrapped about the perform 802. In one exemplary embodiment, the preform 802 may define a rectangle cross-sectional shape for creating planar and/or straight universal substrates (see FIG. 14A). In other exemplary embodiments, a preform may define any suitable cross-sectional shape for creating various types of universal substrates dictated by the implementation of said universal substrates.

Continuing with fabrication process 800, a plurality of conductors 810 that form the batch product 801 are wound and/or wrapped about the outer surface 802A of the preform 802 in a desired orientation and/or arrangement dictated by the implementation of one or more universal substrates wafered from the batch product 801 (see FIG. 14A). It should be noted that the plurality of conductors 810 may be conductors described and illustrated herein (e.g., plurality of conductors 10). In one exemplary embodiment, each conductor of the plurality of conductors 810 that is wound and/or wrapped about the outer surface 802A of the preform 802 may include a shielding and/or nonconductive material that protects and isolates the conductor from the external environment. In another exemplary embodiment, each conductor of the plurality of conductors 810 that is wound and/or wrapped about the outer surface 802A of the preform 802 may be a bare conductor that is free from any having any shielding and/or nonconductive material that protects and isolates the conductor from the external environment.

Once the plurality of conductors 810 are wound about the preform 802, a nonconductive matrix or dielectric material 820 may then be introduced to the preform 802 and the plurality of conductors 810. As best seen in FIG. 14A, the nonconductive matrix 820 is applied to the preform 802 and the plurality of conductors 810 wherein the nonconductive matrix 820 permeates the interstitial space between the plurality of wires 810. Such permeation of the nonconductive matrix 820 allows the nonconductive matrix 820 to bond with the plurality of conductors 810 to hold and maintain the plurality of conductors 810 with one another at the desired shape of the preform 802 to create the batch product 801. Such permeation of the nonconductive matrix 820 also separates and/or isolates the plurality of conductors 810 from one another in a longitudinal direction and a lateral direction as previously discussed above. It should be noted that the nonconductive matrix and/or dielectric material may be any nonconductive matrix described and illustrated herein (e.g., nonconductive matrix 20).

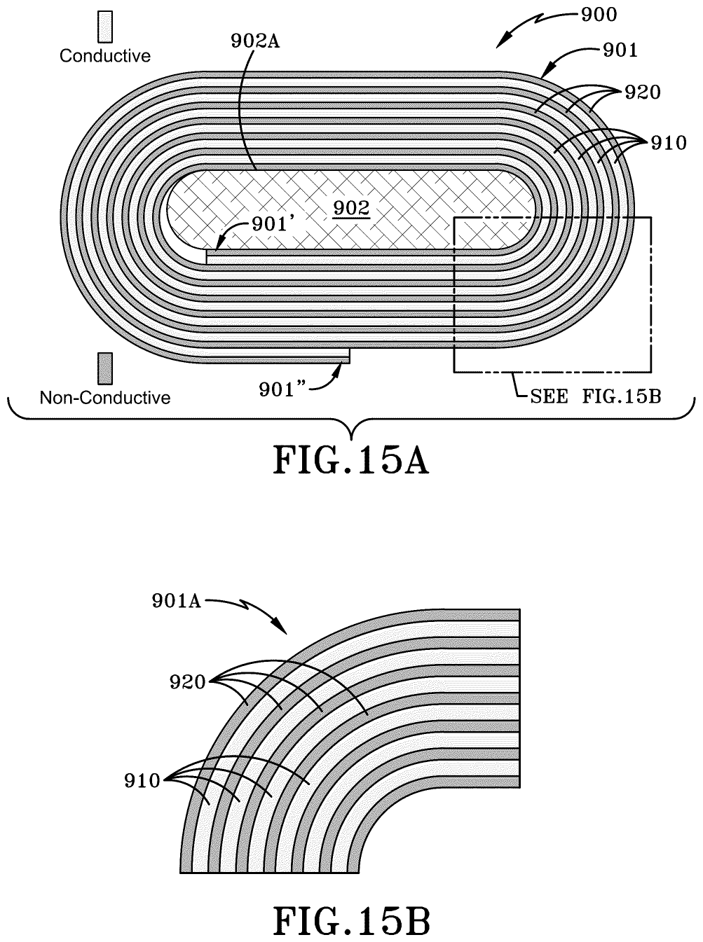

Once the batch product 801 is formed, a section 801A of the batch product 801 may be removed from the batch product 801 for creating one or more individual universal substrates (e.g., universal substrate 801) (see FIG. 15B). Once removed, the section 801A of the batch product 801 may then be cut and/or wafered into one or more individual universal substrates 801B having a desired parameters dictated by the implementation of the one or more individual universal substrates 801B (see FIG. 15C). It should be understood that any suitable equipment and/or tools may be used to remove one or more sections 801A from the batch product 801 and to wafer one or more individual universal substrates 801B from the one or more sections 801A. It should also be noted that the one or more individual universal substrates 801B may be any universal substrate discussed herein, including universal substrate 1, 101, 201, 301, 401, 501, 601, and 701.

Upon such wafering of the one or more universal substrates 801B, additional tools and/or equipment may be used to machine and/or form various features into one or more universal substrates 810B. In one exemplary embodiment, tools and/or equipment may be used to machine linear, non-linear, and/or stepped profiles into one or more universal substrates 801B (e.g., universal substrate 601). In another exemplary embodiment, tools and/or equipment may be used to remove one or more conductors 810 and nonconductive matrix 820 from one or more universal substrates 801B to define apertures, vias, and/or voids in the one or more universal substrates 801B (e.g., universal substrate 701).

FIGS. 15A-15B illustrate another fabrication process 900 for creating a batch product 901 that may be wafered into one or more universal substrates described and illustrated herein (e.g., universal substrate 1). Such components of the used in fabricating a batch product 901 for the fabrication process 900 are discussed in greater detail below.

Initially, a preform or template 902 that defines a predetermined and/or desired outer profile for fabricating a batch universal product 901 (hereinafter “batch product”) that may be wafered into one or more universal substrates described and illustrated herein (similar to universal substrate 1). As best seen in FIG. 15A, the preform 902 includes an outer surface 902A that is continuous along the entire length of the preform 902 for holding one or more conductors of a batch product 901, which is discussed in greater detail below. Similar to batch product 801, a first end 901′ of the batch product 901 is engaged with the outer surface 902A of the perform 902, and a second end 901″ of the batch product 901 is opposite to the first end 901′ and is spaced apart from the perform 902 due to the batch product 901 being wrapped about the perform 902. In the illustrated embodiment, the preform 902 defines a circular and/or round cross-sectional shape for creating round and/or non-linear universal substrates. In other exemplary embodiments, a preform may define any suitable cross-sectional shape for creating various types of universal substrates dictated by the implementation of said universal substrates.

Continuing with fabrication process 900, a plurality of conductors 910 that form the batch product 901 are wound and/or wrapped about the outer surface 902A of the preform 902 in a desired orientation and/or arrangement dictated by the implementation of one or more universal substrates wafered from the batch product 901 (see FIG. 15A). It should be noted that the plurality of conductors 910 may be conductors described and illustrated herein (e.g., plurality of conductors 10). In one exemplary embodiment, each conductor of the plurality of conductors 910 that is wound and/or wrapped about the outer surface 902A of the preform 902 may include a shielding and/or nonconductive material that protects and isolates the conductor from the external environment. In another exemplary embodiment, each conductor of the plurality of conductors 910 that is wound and/or wrapped about the outer surface 902A of the preform 902 may be a bare conductor that is free from any having any shielding and/or nonconductive material that protects and isolates the conductor from the external environment.

Once the plurality of conductors 910 are wound about the preform 902, a nonconductive matrix or dielectric material 920 may then be introduced to the preform 902 and the plurality of conductors 910. As best seen in FIG. 15A, the nonconductive matrix 920 is applied to the preform 902 and the plurality of conductors 910 wherein the nonconductive matrix 920 permeates the interstitial space between the plurality of wires 910. Such permeation of the nonconductive matrix 920 allows the nonconductive matrix 920 to bond with the plurality of conductors 910 to hold and maintain the plurality of conductors 910 with one another at the desired shape of the preform 902 to create the batch product 901. Such permeation of the nonconductive matrix 920 also separates and/or isolates the plurality of conductors 910 from one another in a longitudinal direction and a lateral direction as previously discussed above. It should be noted that the nonconductive matrix and/or dielectric material may be any nonconductive matrix described and illustrated herein (e.g., nonconductive matrix 20).

Once the batch product 901 is formed, a section 901A of the batch product 901 may be removed from the batch product 901 for creating one or more individual universal substrates (e.g., universal substrate 901) (see FIG. 15B). In this embodiment, the section 901A of batch product 901 defines a curvilinear shape and/or arcuate shape based on the outer surface 902A of the preform 902. Such curvilinear shape and/or arcuate shape of the section 901A is considered advantageous for connecting at least two radiofrequency (RF) devices 904 or similar electronic devices with one another for directing and sending electronic signals between the at least two RF devices by the section 901A.

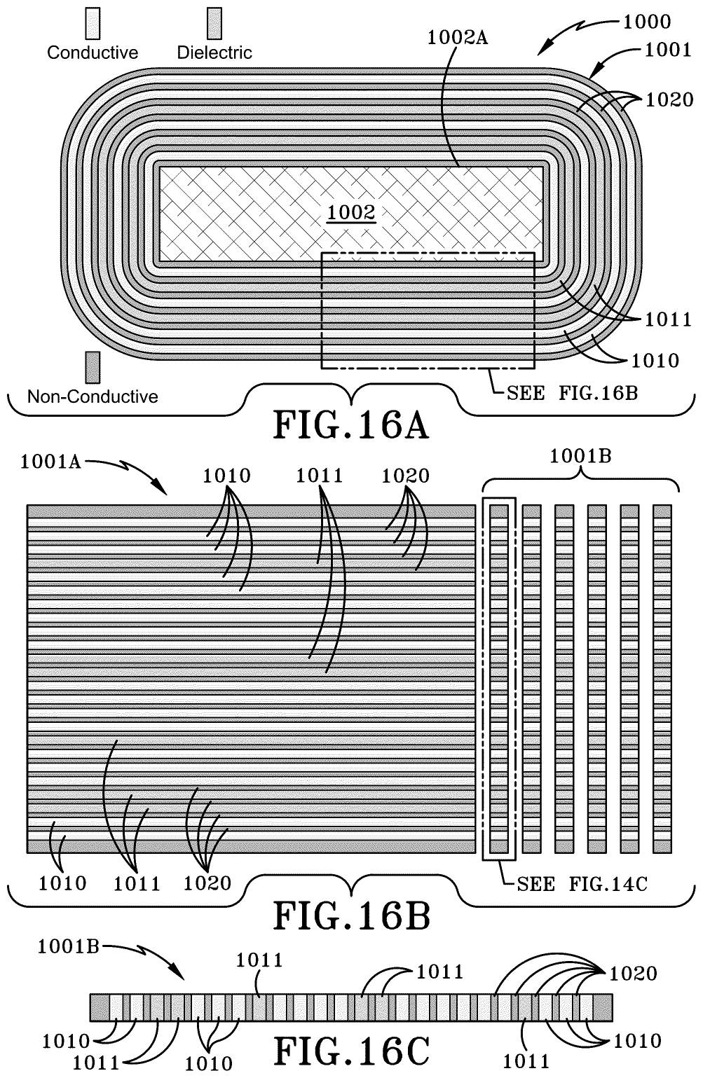

FIGS. 16A-16C illustrate a fabrication process 1000 for creating a batch product 1001 that may be wafered into one or more universal substrates described and illustrated herein (e.g., universal substrate 1). Such components of the used in fabricating a batch product 1001 for the fabrication process 1000 are discussed in greater detail below.

Initially, a preform or template 1002 that defines a predetermined and/or desired outer profile for fabricating a batch universal product 1001 (hereinafter “batch product”) that may be wafered into one or more universal substrates described and illustrated herein (similar to universal substrate 1). As best seen in FIG. 16A, the preform 1002 includes an outer surface 1002A that is continuous along the entire length of the preform 1002 for holding one or more conductors of a batch product 1001, which is discussed in greater detail below. In one exemplary embodiment, the preform 1002 may define a rectangle cross-sectional shape for creating planar and/or straight universal substrates (see FIG. 16A). In other exemplary embodiments, a preform may define any suitable cross-sectional shape for creating various types of universal substrates dictated by the implementation of said universal substrates.

It should be understood that while batch product 1001 is shown in a concentric configuration for diagrammatic purposes, the batch product 1001 may be shown as having two ends (similar to batch products 801, 901) where a first end is engaged with the outer surface 1002A of the perform 1002, and a second end is opposite to the first end and is spaced apart from the perform 1002 due to the batch product being wrapped about the perform 1002.

Continuing with fabrication process 1000, a plurality of conductors 1010 that form the batch product 1001 are wound and/or wrapped about the outer surface 1002A of the preform 1002 in a desired orientation and/or arrangement dictated by the implementation of one or more universal substrates wafered from the batch product 1001 (see FIG. 16A). It should be noted that the plurality of conductors 1010 may be conductors described and illustrated herein (e.g., plurality of conductors 10). In one exemplary embodiment, each conductor of the plurality of conductors 1010 that is wound and/or wrapped about the outer surface 1002A of the preform 1002 may include a shielding and/or nonconductive material that protects and isolates the conductor from the external environment. In another exemplary embodiment, each conductor of the plurality of conductors 1010 that is wound and/or wrapped about the outer surface 1002A of the preform 1002 may be a bare conductor that is free from any having any shielding and/or nonconductive material that protects and isolates the conductor from the external environment.

In this embodiment, a set of nonconductors strands or blanks 1011 may also be used to form the batch product 1001. As best seen in FIG. 16A, the set of blanks 1011 are wound and/or wrapped about the outer surface 1002A of the preform 1002 in a desired orientation and/or arrangement dictated by the implementation of one or more universal substrates wafered from the batch product 1001. Such inclusion of the set of blanks 1011 into batch product 1001 may provide the batch product 1001 with conductive areas (provided by the plurality of conductors 1010) and nonconductive areas (provided by the set of blanks 1011) selected and/or predetermined by the designer of the batch product 1001.

In the present disclosure, each conductor of the plurality of conductors 1010 is shown as a single strand of metallic material having a continuous diameter and/or shape defined along the entire length of each strand of metallic material. In other exemplary embodiments, a plurality of conductors of a batch product may include two or more conductors that have different geometries and/or configurations dictated by the implementation of one or more universal substrates wafered from batch product. In one instance, a plurality of conductors of a batch product may include at least one set of conductors having a first geometric shape or configuration (e.g., a single strand of metallic wire having a continuous diameter) and at least another set of conductors having a second geometric shape or configuration different than the at least one set of conductors (e.g., twisted pairs of wires, coax cables, etc.).

In the present disclosure, the set of blanks 1011 used in batch product 1001 are dielectric strands and/or materials that inhibit and/or prevent conductivity in a vertical axis along a universal substrate. In one exemplary embodiment, each blank of a set of blanks may be formed from a nonmetallic, dielectric material that prevents electric current from flowing freely inside of a batch product. In another exemplary embodiment, each blank of a set of blanks may also be a metallic component that has an electrical resistance or volume resistance greater than a plurality of conductors used in a batch product for resisting a desired and/or predetermined unit of electric current.

Once the plurality of conductors 1010 are wound about the preform 1002, a nonconductive matrix or dielectric material 1020 may then be introduced to the preform 1002, the plurality of conductors 1010, and the set of blanks 1011. As best seen in FIG. 16A, the nonconductive matrix 1020 is applied to the preform 1002, the plurality of conductors 1010, and the set of blanks 1011 wherein the nonconductive matrix 1020 permeates the interstitial space between the plurality of wires 1010 and the set of blanks 1011. Such permeation of the nonconductive matrix 1020 allows the nonconductive matrix 1020 to bond with the plurality of conductors 1010 and the set of blanks 1011 to hold and maintain the plurality of conductors 1010 and the set of blanks 1011 with one another at the desired shape of the preform 1002 to create the batch product 1001. Such permeation of the nonconductive matrix 1020 also separates and/or isolates the plurality of conductors 1010 from one another in a longitudinal direction and a lateral direction as previously discussed above. It should be noted that the nonconductive matrix and/or dielectric material may be any nonconductive matrix described and illustrated herein (e.g., nonconductive matrix 20).

Once the batch product 1001 is formed, a section 1001A of the batch product 1001 may be removed from the batch product 1001 for creating one or more individual universal substrates (e.g., universal substrate 1001) (see FIG. 16B). Once removed, the section 1001A of the batch product 1001 may then be cut and/or wafered into one or more individual universal substrates 1001B having a desired parameters dictated by the implementation of the one or more individual universal substrates 1001B (see FIG. 16C). It should be understood that any suitable equipment and/or tools may be used to remove one or more sections 1001A from the batch product 1001 and to wafer one or more individual universal substrates 1001B from the one or more sections 1001A. It should also be noted that the one or more individual universal substrates 1001B may be any universal substrate discussed herein, including universal substrate 1, 101, 201, 301, 401, 501, 601, and 701.

Upon such wafering of the one or more universal substrates 1001B, additional tools and/or equipment may be used to machine and/or form various features into one or more universal substrates 1010B. In one exemplary embodiment, tools and/or equipment may be used to machine linear, non-linear, and/or stepped profiles into one or more universal substrates 1001B (e.g., universal substrate 601). In another exemplary embodiment, tools and/or equipment may be used to remove one or more conductors 1010 and nonconductive matrix 1002 from one or more universal substrates 1001B to define apertures, vias, and/or voids in the one or more universal substrates 1001B (e.g., universal substrate 701).

It should be understood that any universal substrate discussed herein, including universal substrates 1, 101, 201, 301, 401, 501, 601, 701, 801, 901, and 1001, may yield a low or height aspect ratio for through substrate vias. In one exemplary embodiment, a universal substrate discussed herein may include an aspect ratio range of about 1:1 up to about 10:1. In another exemplary embodiment, a universal substrate discussed herein may include an aspect ratio range of about 1:1 up to about 100:1. In yet another exemplary embodiment, a universal substrate discussed herein may include an aspect ratio range of about 1:1 up to about 1000:1.

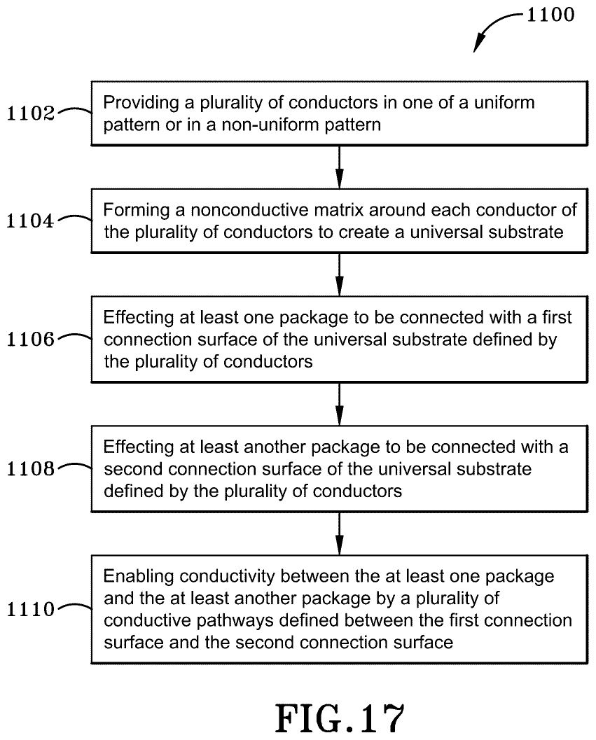

FIG. 17 illustrates a method 1100. An initial step 1102 of method 1100 includes providing a plurality of conductors in one of a uniform pattern or in a non-uniform pattern. Another step 1104 of method 1100 includes forming a nonconductive matrix around each conductor of the plurality of conductors to create a universal substrate. Another step 1106 of method 1100 includes effecting at least one device to be connected with a first connection surface of the universal substrate defined by the plurality of conductors. Another step 1108 of method 1100 includes effecting at least another device to be connected with a second connection surface of the universal substrate defined by the plurality of conductors. Another step 1110 of method 1100 includes enabling conductivity between the at least one device and the at least another device by a plurality of conductive pathways defined between the first connection surface and the second connection surface.

In other exemplary embodiments, method 1100 may include optional and/or additional steps. An optional step may further include that the step of forming the nonconductive matrix around each conductor of the plurality of conductors further comprising: insulating each conductor of the plurality of conductors from one another, by the nonconductive matrix, along axes that are perpendicular to the plurality of conductive pathways. Optional steps may further include that the steps of effecting the at least one device to be connected with the first connection surface and effecting the at least another device to be connected with the second connection surface further includes: connecting the at least one device and the at least another device with at least one conductor of the plurality of conductors such that the at least one device and the at least another device are coaxial with one another with respect to the at least one conductor or offset with one another with respect to the at least one conductor. Optional steps may further include that the steps of effecting the at least one device to be connected with the first connection surface and effecting the at least another device to be connected with the second connection surface further includes: connecting the at least one device with a pair of first bonding pads collectively defined by first connection ends of at least one set of conductors of the plurality of conductors and second connection ends of the at least one set of conductors of the plurality of conductors; and connecting the at least another device with a pair of second bonding pads defined by first connection ends of at least another set of conductors of the plurality of conductors and second connection ends of the at least another set of conductors of the plurality of conductors; wherein the pair of first bonding pads and the pair of second bonding pads have diameters equal to one another or different to one another. Optional steps may further include that the steps of effecting the at least one device to be connected with the first connection surface and effecting the at least another device to be connected with the second connection surface further includes: connecting the at least one device with a set of first conductors at the first connection surface and the at least another device with the set of first conductors at the second connection surface; and connecting the at least one device with a set of second conductors at the first connection surface and the at least another device with the set of second conductors at the second connection surface; wherein at least two conductors of the set of second conductors shield at least one conductor of the set of first conductors. Optional steps may further include that the steps of effecting the at least one device to be connected with the first connection surface and effecting the at least another device to be connected with the second connection surface further includes that the at least one device and the at least another device are free to connect with the first connection surface and the second connection surface at non-designated positions. An optional step may further include that the step of enabling conductivity between the at least one device and the at least another device by the plurality of conductive pathways further includes that the plurality of conductive pathways provides electrical conductivity between the at least one device and the at least another device or thermally conductive between the at least one device and the at least another device to provide directional heat flow through the nonconductive matrix.

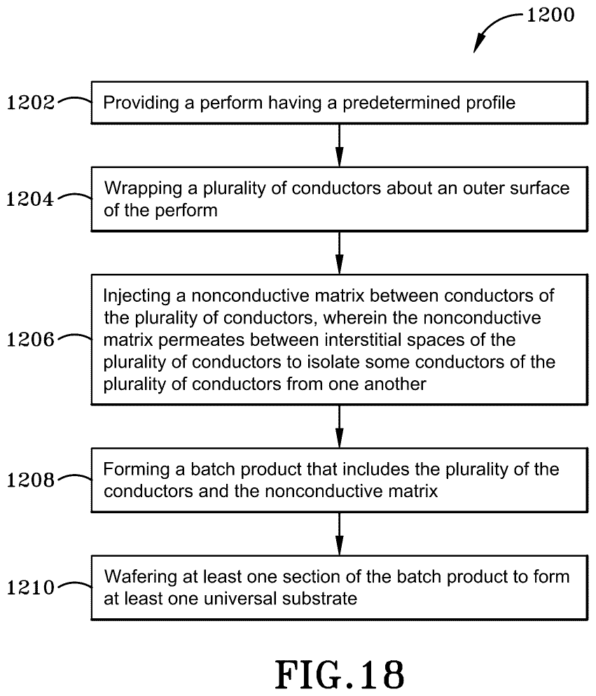

FIG. 18 illustrates a method 1200. An initial step 1202 of method 1200 includes providing a preform having a predetermined profile. Another step 1204 of method 1200 includes wrapping a plurality of conductors about an outer surface of the preform. Another step 1206 of method 1200 includes injecting a nonconductive matrix between conductors of the plurality of conductors, wherein the nonconductive matrix permeates between interstitial spaces of the plurality of conductors to isolate some conductors of the plurality of conductors from one another. Another step 1208 of method 1200 includes forming a batch product that includes the plurality of conductors and the nonconductive matrix. Another step 1210 of method 1200 includes wafering at least one section of the batch product to form at least one universal substrate, wherein the plurality of conductors of the at least one universal substrate defines a first connection surface, a second connection surface opposite to the first connection surface, and a plurality of conductive pathways defined between the first connection surface and the second connection surface.

In other exemplary embodiments, method 1200 may include optional and/or additional steps. Method 1200 may further include that the plurality of conductors of the at least one universal substrate is one of electrically conductive between the first connection surface and the second connection surface to provide electrical communication between at least two devices and thermally conductive between the first connection surface and the second connection surface to provide directional heat flow through the at least one universal substrate between the at least two devices. An optional step of method 1200 may further include that the step of wrapping the plurality of conductors further includes: wrapping the plurality of conductors in one of a uniform pattern or in a non-uniform pattern about the outer surface of the preform. An optional step of method 1200 may further include the step of wrapping the plurality of conductors further includes that each conductor of the plurality of conductors defines a diameter defined between a first connection end that defines a portion of the first connection surface and a second connection end that defines a portion of the second connection surface; wherein the diameter of each conductor of the plurality of conductors is equal to one another. An optional step of method 1200 may further include that the step of wrapping the plurality of conductors further comprises: wrapping a first set of conductors of the plurality of conductors about the outer surface of the preform, wherein each conductor of the first set of conductors defines a first diameter defined between a first connection end that defines a portion of the first connection surface and a second connection end that defines a portion of the second connection surface; and wrapping a second set of conductors of the plurality of conductors about the outer surface of the preform, wherein each conductor of the second set of conductors defines a second diameter defined between a first connection end that defines a portion of the first connection surface and a second connection end that defines a portion of the second connection surface; wherein the second diameters of the second set of conductors are greater than the first diameters of the first set of conductors. Optional steps of method 1200 may further include engaging a pair of first bonding pads to first connections of a first set of conductors of the plurality of conductors of the at least one universal substrate and to second connections of the first set of conductors of the plurality of conductors of the at least one universal substrate; and engaging a pair of second bonding pads to first connections of a second set of conductors of the plurality of conductors of the at least one universal substrate and to second connections of the second set of conductors of the plurality of conductors of the at least one universal substrate; wherein the pair of first bonding pads and the pair of second bonding pads have diameters that are equal to one another or different from one another. Optional steps of method 1200 may further include encapsulating the at least one universal substrate with a passivation material; and removing sections of the passivation material from the at least one universal substrate prior to engaging the pair of first bonding pads and the pair of second bonding pads. Optional steps of method 1200 may further include effecting a set of first conductors of the plurality of conductors of the at least one universal substrate to be conductively engaged with a first electronic device of at least two devices at the first connection surface and a second electronic device of the at least two devices at the second connection surface; and effecting a set of second conductors of the plurality of conductors of the at least one universal substrate to be conductively disengaged from the at least two devices at the first connection surface and the second connection surface; wherein at least one conductor of the set of second conductors separates a first group of the set of first conductors and a second group of the set of first conductors from one another. Optional steps of method 1200 may further include effecting a set of first conductors of the plurality of conductors of the at least one universal substrate to be conductively engaged with a first electronic device of at least two devices at the first connection surface and a second electronic device of the at least two devices at the second connection surface; effecting a set of second conductors of the plurality of conductors of the at least one universal substrate to be conductivity disengaged from the at least two devices at the first connection surface and the second connection surface; and effecting a set of third conductors of the plurality of conductors of the at least one universal substrate to be conductively engaged with the first electronic device at the first connection surface and the second electronic device at the second connection surface; wherein at least two conductors of the set of third conductors shield at least one conductor of the set of first conductors. An optional step of method 1200 may further include effecting at least one conductive tracing to be conductively engaged with at least one of the first connection surface and the second connection surface of the at least one universal substrate; wherein the at least one conductive tracing is adapted to provide conductivity between a first electronic device of the at least two devices and a second electronic device of the at least two devices that are non-coaxial with one another. An optional step of method 1200 may further include wrapping a plurality of dielectric strands about the outer surface of the preform. Method 1200 may further include that step of the providing the preform having the predetermined profile further includes that the preform defines a rounded profile having a rounded outer surface; and wherein the step of wafering the at least one section of the batch product to form the at least one universal substrate further includes that the at least universal substrate defines a round configuration. Optional steps of method 1200 may further include effecting a first radiofrequency (RF) connection of the at least one universal substrate to be conductively engaged with a first RF device; and effecting a second radiofrequency (RF) connection of the at least one universal substrate to be conductively engaged with a second RF device. An optional step of method 1200 may further include machining a third connection surface defined between the first connection surface and the second connection surface of the at least one universal substrate. Optional steps of method 1200 may further include effecting a set of first conductors of the plurality of conductors of the at least one universal substrate to be conductively engaged with a first electronic device at the first connection surface and a second electronic device at the second connection surface; and effecting a set of second conductors of the plurality of conductors of the at least one universal substrate to be conductively engaged with a third electronic device at the third connection surface and the second electronic device at the second connection surface; wherein the third electronic device is positioned between the first electronic device and the second electronic device. An optional step of method 1200 may further include machining at least via defined between at least one set of conductors of the plurality of conductors and at least another set of conductors of the plurality of conductors. Optional steps of method 1200 may further include effecting the plurality of conductors of the at least one universal substrate to be conductively engaged with a first electronic device at the first connection surface and a second electronic device of the at least two devices at the second connection surface; and effecting a third electronic device to be disposed inside of the at least one universal substrate between the at least one set of conductors and the at least another set of conductors and be conductively engaged with the second electronic device; wherein the plurality of conductors of the at least one universal substrate is free from conductively engaging with the third electronic device. Method 1200 may further include that the step of wafering the at least one section of the batch product to form at least one universal substrate further includes that a thickness of the at least one universal substrate is of at least 100 micrometers. Method 1200 may further include a ratio of the plurality of conductors for the at least one universal substrate is greater than 10:1.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

While components of the present disclosure are described herein in relation to each other, it is possible for one of the components disclosed herein to include inventive subject matter, if claimed alone or used alone. In keeping with the above example, if the disclosed embodiments teach the features of components A and B, then there may be inventive subject matter in the combination of A and B, A alone, or B alone, unless otherwise stated herein.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party.

Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

To the extent that the present disclosure has utilized the term “invention” in various titles or sections of this specification, this term was included as required by the formatting requirements of word document submissions pursuant the guidelines/requirements of the United States Patent and Trademark Office and shall not, in any manner, be considered a disavowal of any subject matter.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

What is claimed is:

1. A method, comprising:
providing a preform having a predetermined profile;
wrapping a plurality of conductors about an outer surface of the preform;
injecting a nonconductive matrix between conductors of the plurality of conductors, wherein the nonconductive matrix permeates between interstitial spaces of the plurality of conductors to isolate some conductors of the plurality of conductors from one another;
forming a batch product that includes the plurality of conductors and the nonconductive matrix; and
wafering at least one section of the batch product to form at least one universal substrate, wherein the plurality of conductors of the at least one universal substrate defines a first connection surface, a second connection surface opposite to the first connection surface, and a plurality of conductive pathways defined between the first connection surface and the second connection surface.

2. The method of claim 1, wherein the plurality of conductors of the at least one universal substrate is one of electrically conductive between the first connection surface and the second connection surface to provide electrical communication between at least two devices and thermally conductive between the first connection surface and the second connection surface to provide directional heat flow through the at least one universal substrate between the at least two devices.

3. The method of claim 1, wherein the step of wrapping the plurality of conductors further includes:
wrapping the plurality of conductors in one of a uniform pattern or in a non-uniform pattern about the outer surface of the preform.

4. The method of claim 1, wherein the step of wrapping the plurality of conductors further includes that each conductor of the plurality of conductors defines a diameter defined between a first connection end that defines a portion of the first connection surface and a second connection end that defines a portion of the second connection surface;
wherein the diameter of each conductor of the plurality of conductors is equal to one another.

5. The method of claim 1, wherein the step of wrapping the plurality of conductors further comprises:
wrapping a first set of conductors of the plurality of conductors about the outer surface of the preform, wherein each conductor of the first set of conductors defines a first diameter defined between a first connection end that defines a portion of the first connection surface and a second connection end that defines a portion of the second connection surface; and
wrapping a second set of conductors of the plurality of conductors about the outer surface of the preform, wherein each conductor of the second set of conductors defines a second diameter defined between a first connection end that defines a portion of the first connection surface and a second connection end that defines a portion of the second connection surface;
wherein the second diameters of the second set of conductors are greater than the first diameters of the first set of conductors.

6. The method of claim 1, further comprising:
engaging a pair of first bonding pads to first connections of a first set of conductors of the plurality of conductors of the at least one universal substrate and to second connections of the first set of conductors of the plurality of conductors of the at least one universal substrate; and
engaging a pair of second bonding pads to first connections of a second set of conductors of the plurality of conductors of the at least one universal substrate and to second connections of the second set of conductors of the plurality of conductors of the at least one universal substrate;
wherein the pair of first bonding pads and the pair of second bonding pads have diameters that are equal to one another or different from one another.

7. The method of claim 6, further comprising:
encapsulating the at least one universal substrate with a passivation material; and
removing sections of the passivation material from the at least one universal substrate prior to engaging the pair of first bonding pads and the pair of second bonding pads.

8. The method of claim 1, further comprising:
effecting a set of first conductors of the plurality of conductors of the at least one universal substrate to be conductively engaged with a first electronic device of at least two devices at the first connection surface and a second electronic device of the at least two devices at the second connection surface; and
effecting a set of second conductors of the plurality of conductors of the at least one universal substrate to be conductively disengaged from the at least two devices at the first connection surface and the second connection surface;
wherein at least one conductor of the set of second conductors separates a first group of the set of first conductors and a second group of the set of first conductors from one another.

9. The method of claim 1, further comprising:
effecting a set of first conductors of the plurality of conductors of the at least one universal substrate to be conductively engaged with a first electronic device of at least two devices at the first connection surface and a second electronic device of the at least two devices at the second connection surface;
effecting a set of second conductors of the plurality of conductors of the at least one universal substrate to be conductivity disengaged from the at least two devices at the first connection surface and the second connection surface; and
effecting a set of third conductors of the plurality of conductors of the at least one universal substrate to be conductively engaged with the first electronic device at the first connection surface and the second electronic device at the second connection surface;
wherein at least two conductors of the set of third conductors shield at least one conductor of the set of first conductors.

10. The method of claim 1, further comprising:
effecting at least one conductive tracing to be conductively engaged with at least one of the first connection surface and the second connection surface of the at least one universal substrate;
wherein the at least one conductive tracing is adapted to provide conductivity between a first electronic device of the at least two devices and a second electronic device of the at least two devices that are non-coaxial with one another.

11. The method of claim 1, further comprising:
wrapping a plurality of dielectric strands about the outer surface of the preform.

12. The method of claim 1, wherein the step of the providing the preform having the predetermined profile further includes that the preform defines a rounded profile having a rounded outer surface; and
wherein the step of wafering the at least one section of the batch product to form the at least one universal substrate further includes that the at least universal substrate defines a round configuration.

13. The method of claim 12, further comprising:
effecting a first radiofrequency (RF) connection of the at least one universal substrate to be conductively engaged with a first RF device; and
effecting a second radiofrequency (RF) connection of the at least one universal substrate to be conductively engaged with a second RF device.

14. The method of claim 1, further comprising:
machining a third connection surface defined between the first connection surface and the second connection surface of the at least one universal substrate.

15. The method of claim 14, further comprising:
effecting a set of first conductors of the plurality of conductors of the at least one universal substrate to be conductively engaged with a first electronic device at the first connection surface and a second electronic device at the second connection surface; and
effecting a set of second conductors of the plurality of conductors of the at least one universal substrate to be conductively engaged with a third electronic device at the third connection surface and the second electronic device at the second connection surface;
wherein the third electronic device is positioned between the first electronic device and the second electronic device.

16. The method of claim 1, further comprising:
machining at least via defined between at least one set of conductors of the plurality of conductors and at least another set of conductors of the plurality of conductors.

17. The method of claim 16, further comprising:
effecting the plurality of conductors of the at least one universal substrate to be conductively engaged with a first electronic device at the first connection surface and a second electronic device of the at least two devices at the second connection surface; and
effecting a third electronic device to be disposed inside of the at least one universal substrate between the at least one set of conductors and the at least another set of conductors and be conductively engaged with the second electronic device;
wherein the plurality of conductors of the at least one universal substrate is free from conductively engaging with the third electronic device.

18. The method of claim 1, wherein the step of wafering the at least one section of the batch product to form at least one universal substrate further includes that a thickness of the at least one universal substrate is of at least 100 micrometers.

19. The method of claim 1, wherein a ratio of the plurality of conductors for the at least one universal substrate is greater than 10:1.

20. A method, comprising:
providing a preform having a predetermined profile;
wrapping a plurality of conductors about an outer surface of the preform;
injecting a nonconductive matrix between conductors of the plurality of conductors, wherein the nonconductive matrix permeates between interstitial spaces of the plurality of conductors to isolate some conductors of the plurality of conductors from one another;
forming a batch product that includes the plurality of conductors and the nonconductive matrix; and
wafering at least one section of the batch product to form at least one universal substrate, wherein the plurality of conductors of the at least one universal substrate defines a first connection surface, a second connection surface opposite to the first connection surface, and a plurality of conductive pathways defined between the first connection surface and the second connection surface;
wherein the plurality of conductors of the at least one universal substrate is one of electrically conductive between the first connection surface and the second connection surface to provide electrical communication between at least two devices and thermally conductive between the first connection surface and the second connection surface to provide directional heat flow through the at least one universal substrate between the at least two devices.
